(19) United States
(12) Patent Application Publication
(10) Pub. No.: US 2003/0075746 A1
(43) Pub. Date: Apr. 24, 2003

(54) Semiconductor device for determining identification code and application thereof

(75) Inventors: Shigenobu Maeda, Tokyo (JP); Koichiro Mashiko, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, TOKYO (JP)

(21) Appl. No.: 10/274,130

(22) Filed: Oct. 21, 2002

Related U.S. Application Data
(63) Continuation-in-part of application No. 10/138,569, filed on May 6, 2002.

(30) Foreign Application Priority Data
Oct. 22, 2001 (JP) 2001-323164
Sep. 2, 2002 (JP) 2002-256797

(51) Int. Cl. H01L 29/76

(52) U.S. Cl. 257/288

(57) ABSTRACT

As a first semiconductor element and a second semiconductor element, provided are two p-type MOS transistors for forming an element pair. These MOS transistors are compared with each other in electronic characteristic and a result of which is utilized for determining binary logic for the element pair. These MOS transistors are integrated and hence, they are equally subjected to ambient temperature. As a result, the result of comparison therebetween in electronic characteristic is unlikely to be subjected to ambient temperature.

### BACKGROUND OF THE INVENTION

1. Field of the Invention

The present invention relates to a technique of utilizing state unique to a semiconductor element as an identification code of a device including such semiconductor element mounted thereon.

2. Description of the Background Art

In recent years experiencing widespread use of digital technology, there have been troubles over illegal copies and illegal use of data. For example, in many cases, a compact disc (CD) as one of data media is not copy-protected against illegal copying. As a result, dead copies, in other words, so-called pirated versions thereof are on the market. To protect data from dead copy, a DVD (digital versatile disc or digital video disc) is provided with a read-only region in which an identification code unique to the DVD is stored. Data is encrypted and then stored using this unique identification code, to combat dead copies. Such technique is introduced in the following non-patent document 1, for example:

[non-patent document 1] Naoshi YAMADA, “Broaden Copyright Protection Starting from DVD”, pp. 143-153, NIKKEI ELECTRONICS, Aug. 13, 2001 issue, NIKKEI BP Inc.

However, the foregoing identification code is artificially written and therefore, the identification code itself can be copied in principle. As a result, once a recording medium is manufactured to include the identification code which is the same as the one stored in an original recording medium, a dead copy thereof can be easily made.

Further, there has been an unauthorized act of changing one's own identification code and disguising oneself as another person in a communication network. In order to prevent such unauthorized act, there has been a technique of storing unique identification code in an information terminal used in the communication network. A program for controlling operation of the information terminal may be changed to be compliant with a new communication system. Therefore, the program has been stored in a rewritable storage medium such as a flash memory which further stores an identification code. Namely, the identification code stored in the recording medium has also been rewritable from the outside, resulting in insufficient prevention of occurrence of the foregoing unauthorized act.

In view of this, a technique has been developed utilizing state unique to a semiconductor element has been developed to assign unique identification code to the information terminal. This technique utilizes the fact that the electronic characteristic of a semiconductor element such as a thin film transistor including polycrystalline semiconductor depends on the crystal structure thereof. Such electronic characteristic is converted into an identification code which is then to be used to a device including this semiconductor element mounted thereon. The technique described here is introduced in the following patent document 1 filed in the name of MITSUBISHI DENKI KABUSHIKI KAISHA, for example:

[patent document 1] Japanese Patent Application Laid-Open No. 2001-7290

(This document corresponds to U.S. patent application Ser. No. 09/457,721 referred to later.)

FIG. 35 is a circuit diagram illustrating arrangement of semiconductor elements introduced in Japanese Patent Application Laid-Open No. 7290. Thin film transistors 101 each including polycrystalline semiconductor are arranged in a matrix with 4 rows and 4 columns, for example. Further, a plurality of word lines WL1 through WL4 and a plurality of bit lines BL1 through BL4 are provided to extend in a direction of row (lateral direction in the plane of the drawing) and in a direction of column (longitudinal direction in the plane of the drawing), respectively.

The word lines WL1 through WL4 each have connection to their respective gate electrodes of four thin film transistors 101 arranged in the direction of row commonly connected thereto. Further, the bit lines BL1 through BL4 each have connection to their respective drain electrodes of four thin film transistors 101 arranged in the direction of column commonly connected thereto. A total of 16 thin film transistors 101 include source electrodes each bearing the same positive potential Vcc applied thereto. The bit lines BL1 through BL4 each have one end grounded through a bit line load 17.

The bit line load 17 has an end opposite to the ground end thereof for establishing connection to an interconnect line 18 to be connected to a sense amplifier not shown. Further, the bit lines BL1 through BL4 each have the other end connected to a pad 15 and the word lines WL1 through WL4 each have one end connected to a pad 16.

When a gate voltage at a prescribed level is applied to a selected one of the word lines WL1 through WL4, drain currents Id1 through Id4 flow in four thin film transistors 101 connected to the selected word line. The drain currents Id1 through Id4 flow through separate bit line loads 17 and therefore, the interconnect lines 18 connected to the bit lines BL1 through BL4 bear their respective potentials developed therein that are proportionate to the drain currents Id1 through Id4. By sequentially applying the gate voltage to the word lines WL1 through WL4, a total of 16 potentials can be taken out.

Together with a reference potential, the potentials thereby applied to the interconnect lines 18 are applied to the respective sense amplifiers. The sense amplifier compares the reference potential and the potential at the interconnect line 18. The result of the comparison, namely, binary logic indicating whether the potential at the interconnect line 18 is higher or lower than the reference potential constitutes an identification code. The binary logic thereby obtained reflects the crystal structure of the polycrystalline semiconductor as a material for each thin film transistor 101. When one reference potential is fixed at a certain level, a 16-bit identification code is obtained accordingly on the basis of variation in characteristic among the 16 thin film transistors 101.

The technique of providing a unique identification code to a semiconductor substrate is introduced in the following patent document 2, for example:

[patent document 2] Japanese Patent Application Laid-Open No. 2002-073424

(This document corresponds to U.S. patent application Ser. No. 09/943,026 referred to later.)

The wireless tag technique is introduced in the following non-patent document 2, for example:

[non-patent document 2] Fumitada TAKAHASHI and Yasuo TANOKURA, pp. 109-137, “Source of Transmission is a sesame-sized chip”, NIKKEI ELECTRONICS, Feb. 25, 2002 issue, NIKKEI BP Inc.

The electronic watermark technique is introduced in the following non-patent documents 3 and 4, for example:

[non-patent document 3] Tomonobu YOSHINO and Toshiyuki YOSHIDA, “A Digital Watermark Technique Based on Region Segmentation”, A-7-7, p. 217, Transactions of the Institute of Electronics, Information and Communication Engineers, 2002

[non-patent document 4] Eri SUZUKI and Kiyoharu AIZAWA, “Object-based Watermarking using Object Shape Features”, A-7-8, p. 218, Transactions of the Institute of Electronics, Information and Communication Engineers, 2002

Further, manipulation technique of a cell using a microfabricated structure is introduced in the following non-patent document 5, for example:

[non-patent document 5] Masao Washizu, “Manipulation of Cell and DNA”, “Techniques of Micromachine and Material”, pp. 37-46, Chapter 8, CMC Publications, Inc.

However, a drain current is generally determined according to gate voltage and ambient temperature. An identification code to be obtained on the basis of the drain current as described above may also be dependent on gate voltage and ambient temperature. In contrast to this, an identification code should desirably be unique to an information terminal.

### SUMMARY OF THE INVENTION

It is therefore a first object of the present invention to provide a technique for generating an identification code that is unlikely to be subjected to environmental conditions. It is a second object of the present invention to suggest the structure of a semiconductor element for facilitating generation of an identification code that randomly varies. Further, it is a third object of the present invention to suggest application of a device utilizing the identification code.

A semiconductor device according to the present invention includes a plurality of element pairs each including a first semiconductor element and a second semiconductor element. The first semiconductor element and the second semiconductor element are compared in electronic characteristic, and a result of which is utilized for determining a binary logic for each of the plurality of element pairs.

Utilizing the binary logic determined for each element pair, an identification code unique to the semiconductor device can be obtained. As the first and second semiconductor elements are integrated, they are equally subjected to ambient temperature. The result of comparison therebetween in electronic characteristic is hence unlikely to be subjected to ambient temperature. As a result, the binary logic determined for each element pair and eventually, the identification code uniquely obtained for the semiconductor device are also unlikely to be subjected to ambient temperature.

The semiconductor device according to the present invention includes a gate electrode, a gate insulating film, and a polycrystalline semiconductor layer. The polycrystalline semiconductor layer includes a channel region, a source region, and a drain region. The gate electrode has a planarized main surface. The polycrystalline semiconductor layer is opposed to the gate electrode through the gate insulating film with an area smaller than that of the main surface.

The surface of the polycrystalline semiconductor layer opposed to the planarized main surface is also planarized. The regularity in crystal structure resulting from the existence of a step defined by the gate electrode is thereby avoided in the polycrystalline semiconductor layer, easily causing variation in crystal structure thereof. As a result, the semiconductor device of the present invention is preferably utilized for obtaining a unique identification code based on the electronic characteristic thereof.

The semiconductor device according to the present invention includes a channel region including polycrystalline semiconductor. At least one of a channel width and a channel length of the channel region has a value that is not less than the same as and not more than 10 times an average value of a diameter of a crystal grain in the polycrystalline semiconductor.

A crystal grain may be entirely included in the channel region with high probability, thereby providing high probability of existence of crystal grain boundary therein. As a result, the semiconductor device of the present invention is preferably utilized for obtaining a unique identification code based on the electronic characteristic thereof.

The semiconductor device according to the present invention includes a polycrystalline semiconductor layer of an approximately Y-shaped configuration, and a gate electrode. The polycrystalline semiconductor layer has a first end, a second end, and a third end. The gate electrode crosses the polycrystalline semiconductor layer defined between the first end and the third end. The gate electrode further crosses the polycrystalline semiconductor layer defined between the second end and the third end. The first end serves as a drain of a first transistor. The second end serves as a drain of a second transistor. The third end serves as a source of the first and second transistors.

The source of the first transistor and the source of the second transistor receive a potential applied thereto at the same position.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram illustrating the structure of a semiconductor integrated circuit according to a first preferred embodiment of the present invention;

FIG. 2 is a plan view illustrating the exemplary structure of a thin film transistor applicable to the present invention;

FIG. 3 is a cross-sectional view taken along a cutting plane line A-A in FIG. 2;

FIG. 4 is a graph showing dependence of drain current on ambient temperature;

FIG. 5 is a graph showing dependence of drain current on gate voltage;

FIG. 6 is a cross-sectional view illustrating the exemplary structure of a semiconductor device according to a second preferred embodiment of the present invention;

FIG. 7 is a plan view illustrating regions A1 and A2 defined in FIG. 6;

FIGS. 8 and 9 are cross-sectional views each illustrating the exemplary steps for providing a thin film transistor following sequence thereof;

FIGS. 10 and 11 are graphs each showing frequency distribution of the length of crystal grain boundary;

FIG. 12 is a circuit diagram illustrating the structure of a semiconductor integrated circuit according to a fourth preferred embodiment of the present invention;

FIG. 13 is a circuit diagram illustrating the structure of an element pair according to the fourth preferred embodiment of the present invention;

FIG. 14 is a circuit diagram illustrating the structure of a semiconductor integrated circuit according to a fifth preferred embodiment of the present invention;

FIG. 15 is a circuit diagram illustrating the structure of a semiconductor integrated circuit according to a preferred modification of the fifth preferred embodiment of the present invention;

FIG. 16 is a circuit diagram illustrating the structure of an element pair according to the preferred modification of the fifth preferred embodiment of the present invention;

FIG. 17 is a conceptual view schematically illustrating a sixth preferred embodiment of the present invention;

FIG. 18 is a conceptual view schematically illustrating a seventh preferred embodiment of the present invention;

FIGS. 19 and 20 are conceptual views each schematically illustrating an eighth preferred embodiment of the present invention;

FIGS. 21 and 22 are conceptual views each schematically illustrating a ninth preferred embodiment of the present invention;

FIGS. 23 and 24 are conceptual views each schematically illustrating a tenth preferred embodiment of the present invention;

FIG. 25 is a conceptual view schematically illustrating an eleventh preferred embodiment of the present invention;

FIG. 26 is a conceptual view schematically illustrating a twelfth preferred embodiment of the present invention;

FIG. 27 is a conceptual view schematically illustrating a thirteenth preferred embodiment of the present invention;

FIG. 28 is a flow chart with respect to the thirteenth preferred embodiment of the present invention;

FIG. 29 illustrates a modification of the thirteenth preferred embodiment of the present invention;

FIG. 30 is a conceptual view illustrating the modification of the thirteenth preferred embodiment of the present invention;

FIG. 31 is a block diagram illustrating a fourteenth preferred embodiment of the present invention;

FIG. 32 is a sectional view illustrating the fourteenth preferred embodiment of the present invention;

FIGS. 33 and 34 are block diagram illustrating a modification of the fourteenth preferred embodiment of the present invention; and

FIG. 35 is a circuit diagram illustrating the technique in the background art.

### DESCRIPTION OF THE PREFERRED EMBODIMENTS

First Preferred Embodiment

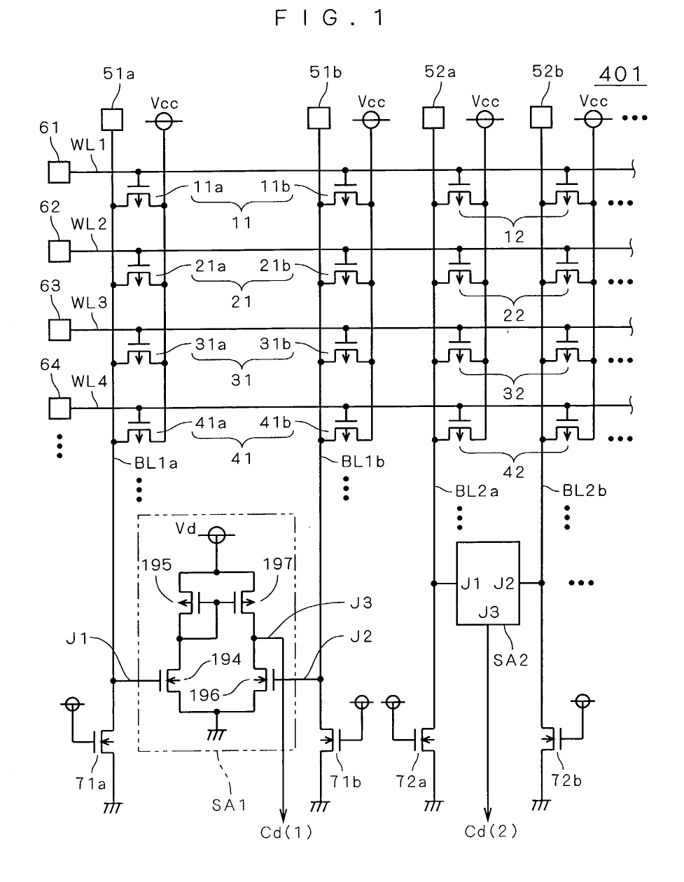

FIG. 1 is a circuit diagram illustrating the structure of a semiconductor integrated circuit according to the first preferred embodiment of the present invention. P-type MOS transistors 11a, 21, 31a, 41a, . . . and p-type MOS transistors 11b, 21b, 31b, 41b, . . . are provided as first semiconductor elements and second semiconductor elements, respectively. The MOS transistors 11a and 11b form an element pair 11, 21a and 21b form an element pair 21, 31a and 31b form an element pair 31 and 41a and 41b form an element pair 41. Similar to the element pairs 11, 21, 31, 41, . . . , further provided are element pairs 12, 22, 32, 42, . . . each including a first semiconductor element and a second semiconductor element.

According to some preferred embodiments of the present invention, the electronic characteristics of the first and second semiconductor elements are compared and the result of which is a determinant of binary logic of each element pair. As the first and second semiconductor elements are integrated, they are equally subjected to ambient temperature. The result of comparison therebetween in electronic characteristic is hence unlikely to be subjected to ambient temperature.

The first preferred embodiment utilizes characteristic of a drain current of an MOS transistor relative to a gate potential of the same (hereinafter referred to as “drain current characteristic”). The drain current characteristic is generally sensitive to the structure of the MOS transistor and therefore, may be preferably utilized as the basis for the comparison between the first and second semiconductor elements to determine binary logic.

For comparison in drain current characteristic, respective source electrodes of the MOS transistors 11a, 21a, 31a, 41a, . . . and 11b, 21b, 31b, 41b, . . . receive the same fixed potential (for example, a positive potential Vcc) applied thereto. A first bit line BL1a connected to each drain electrode of the MOS transistors 11a, 21a, 31a, 41a, . . . and a second bit line BL1b connected to each drain electrode of the MOS transistors 11b, 21b, 31b, 41b, . . . are provided. Similar to the element pairs 11, 21, 31, 41, . . . , the element pairs 12, 22, 32, 42, . . . have their respective connections to a first bit line BL2a and a second bit line BL2b. Further, respective source electrodes of the MOS transistors for forming the element pairs 12, 22, 32, 42, . . . receive the same positive potential Vcc applied thereto.

The first bit lines BL1a, BL2a, . . . are grounded through loads 71a, 72a, . . . , respectively. The second bit lines BL1b, BL2b, . . . are grounded through loads 71b, 72b, . . . , respectively. In FIG. 1, the loads 71a, 72a, 71b and 72b are exemplified as n-type MOS transistors including respective grounded source electrodes, fixed gate potentials and drain electrodes respectively connected to the bit lines BL1a, BL2a, BL1b and BL2b. Similar to the background art, pads 51a, 51b, 52a, 52b, . . . may be provided to one end of the bit lines BL1a, BL2a, BL1b, BL2b, . . . in this order.

A first input terminal J1 and a second input terminal J2 of an sense amplifier SA1 are respectively connected to a node of the first bit line BL1a and the load 71a, and to a node of the second bit line BL1b and the load 71b. Further, first and second input terminals of a sense amplifier SA2 are connected to a node of the first bit line BL2a and the load 72a and to a node of the second bit line BL2b and the load 72b, respectively.

The sense amplifiers SA1, SA2, . . . may be of the same circuit configuration.

FIG. 1 illustrates the exemplary configuration of the sense amplifier SA1. The sense amplifier SA1 includes a series circuit having an n-type MOS transistor 194 and a p-type MOS transistor 195, and a series circuit having an n-type MOS transistor 196 and a p-type MOS transistor 197. These circuits are interposed between a ground and a positive power source Vd. Gate and drain electrodes of the MOS transistor 195 and a gate electrode of the MOS transistor 197 are connected to each other, thereby forming a current mirror circuit. Further, gate electrodes of the MOS transistors 194 and 196 are respectively connected to the first and second input terminals J1 and J2. The inequality between the first and second bit lines BL1a and BL1b in magnitude of current flowing therethrough is thereby outputted as a binary logic Cd(1) of the potential at a node J3 of the MOS transistors 196 and 197.

A word line WL1 is provided correspondingly to the element pairs 11, 12, . . . to be connected to each gate electrode of the MOS transistors for forming these element pairs. Similarly, word lines WL2, WL3 and WL4 are provided correspondingly to the element pairs 21, 22, . . . , 31, 32, . . . and 41, 42, . . . , respectively. Further, pads 61, 62, 63, 64, . . . may be provided to one end of the word lines WL1, WL2, WL3, WL4, . . . in this order as in the background art.

A predetermined potential is applied to the selected one of the word lines WL1, WL2, WL3, WL4, . . . , thereby determining binary logic such as Cd(1) and Cd(2) from the respective element pairs 11, 12, and so forth. The binary logics Cd(1), Cd(2), . . . may differ according to the result of selection from the word lines. Namely, binary logics obtained per sense amplifier differ among the word lines.

As to be described later, when two separate MOS transistors receive the same source potential and gate potential each applied thereto, inequality in magnitude of drain current given between these transistors is unlikely to be subjected to the magnitude of source potential and gate potential. As a result, binary logic is also unlikely to be subjected to variation in potential to be applied to the word line.

The first preferred embodiment thereby allow generation of an identification code having little probability of influence of ambient temperature and potential at the word line.

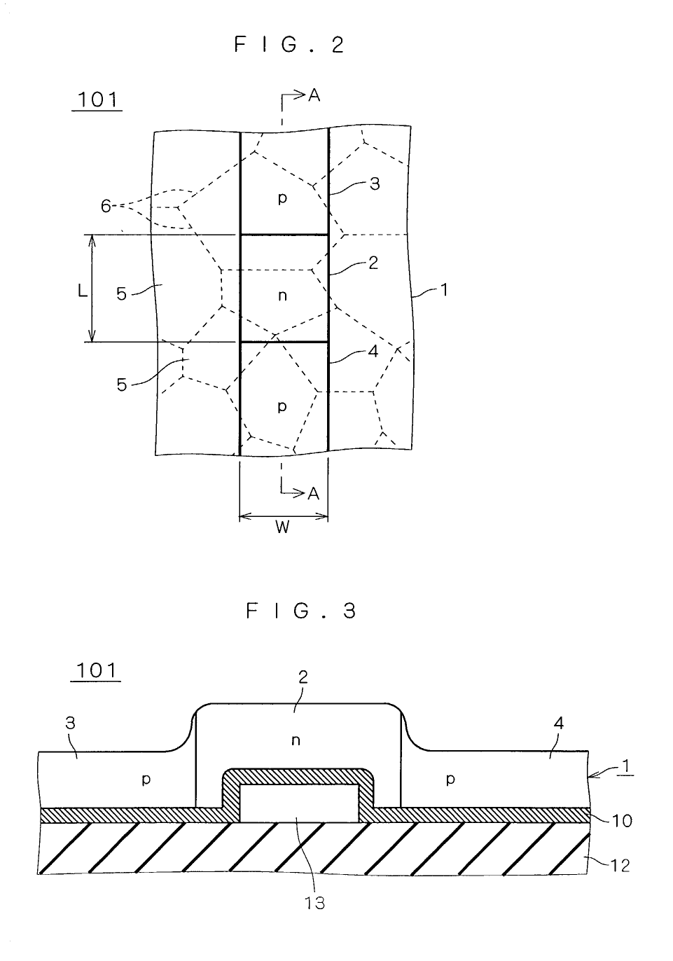

A thin film transistor including polycrystalline semiconductor may be applicable as the MOS transistor such as 11a, 21a, 31a, 41a and 11b, 21b, 31b, 41b. FIG. 2 is a plan view illustrating the exemplary structure of a thin film transistor 101 applicable to the present invention. FIG. 3 is a cross-sectional view taken along the cutting plane line A-A in FIG. 2. The thin film transistor 101 includes polycrystalline semiconductor at least in a channel region thereof.

The thin film transistor 101 has an insulating film 12 and a gate electrode 13 selectively provided thereon. The surfaces of the insulating film 12 and the gate electrode 13 are entirely covered with an insulating film 10. Also provided on the insulating film 10 is a semiconductor layer 1. The exemplary material of each element is as follows. That is, the insulating film 12 includes silicon oxide, the gate electrode 13 includes polysilicon doped with impurities, the insulating film 10 includes silicon oxide such as TEOS and the semiconductor layer 1 mainly includes silicon.

The semiconductor layer 1 includes a channel region 2 arranged above the gate electrode 13 and source, drain regions 3, 4 for holding the channel region 2 interposed therebetween. The portion of the insulating film 10 having contact with the channel region 2 serves as a gate insulating film. The exemplary thin film transistor 101 in the first preferred embodiment is a p-type MOS transistor. Therefore, the channel region 2 has an n-type conductivity while the source and drain regions 3 and 4 each have a p-type conductivity. It is a matter of course that an n-type MOS transistor is also applicable to the present invention.

The semiconductor layer 1 is a polycrystalline semiconductor layer including a plurality of crystal grains 5 and crystal grain boundaries 6 each defined in a boundary surface between adjacent crystal grains. A single crystal grain 5 has a uniform crystal orientation while separate crystal grains 5 generally have their respective orientations. Further, the crystal grains 5 randomly differ thereamong in dimension and location. As a result, while a number of thin film transistors 101 may be identical in macroscopic structure, they are likely to randomly differ thereamong in crystal structure of the semiconductor layer 1, namely, in microscopic structure thereof. The thin film transistor including polycrystalline semiconductor is generally known to possess characteristic that is to vary according to the amount of crystal grains included in the channel region (as introduced in IEEE Transactions on Electron Devices, Vol. 45, No. 1, January (1998), pp. 165-172, for example). In light of this, utilizing the thin film transistor 101 as the MOS transistor such as 11a, 21a, 31a, 41a and 11b, 21b, 31b, 41b, an identification code can be obtained that randomly differs from one semiconductor integrated circuit to another.

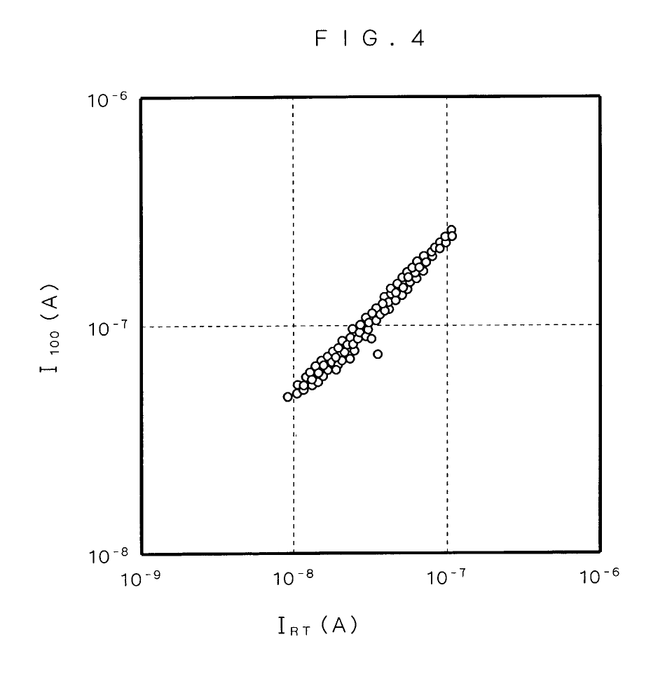

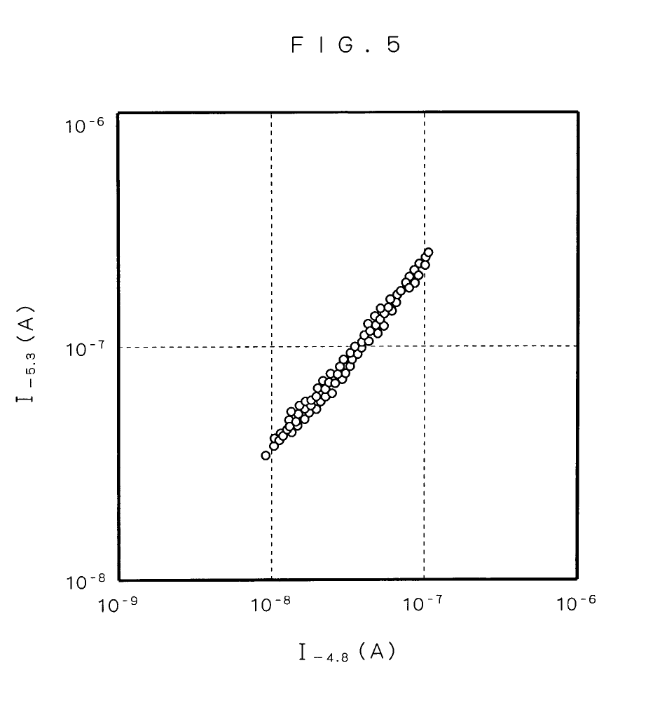

FIGS. 4 and 5 are graphs respectively showing dependence of drain current on ambient temperature and on gate potential, provided by measurement results obtained from a number of thin film transistors 101.

In FIG. 4, the horizontal axis indicates magnitude of a drain current I_{RT} at a room temperature while the vertical axis indicates that of a drain current I₁₀₀ at a temperature of 100° C. More particularly, for each of the drain currents I_{RT} and I₁₀₀, drain and gate potential are respectively set at −1.8 V and −4.8 V relative to a source potential. As shown in this graph, there is a definitely positive correlation between the currents I_{RT} and I₁₀₀. In view of this, it is seen that the result of comparison in drain current between two separate thin film transistors 101 (namely, the result indicating which transistor receives higher current) is unlikely to be subjected to ambient temperature.

In FIG. 5, the horizontal axis indicates magnitude of a drain current I_{-4.8} with a gate potential of −4.8 V while the vertical axis indicates that of a drain current I_{-5.3} with a gate potential of −5.3 V. More particularly, for each of the drain currents L_{-4.8} and L_{-5.3}, a drain potential is set at −1.8 V relative to a source potential. As shown in this graph, there is a definitely positive correlation between the currents I_{-4 8} and I_{-5.3}. In view of this, it is seen that the result of comparison in drain current between two separate thin film transistors 101 (namely, the result indicating which transistor receives higher current) is unlikely to be subjected to gate potential and eventually, unlikely to be subjected to potential at word line.

The thin film transistor 101 may alternatively have channel region 2 solely including polycrystalline semiconductor and source, drain regions 3, 4 each including single-crystalline semiconductor, possibly resulting in increase in complexity of the manufacturing steps. In this case, drain current characteristic also randomly varies.

The type of the semiconductor element to be applied as the MOS transistor such as 11a, 21a, 31a, 41a and 11b, 21b, 31b, 41b is not limited to a thin film transistor including polycrystalline semiconductor having a tendency to randomly vary in microscopic structure from one transistor to another. Even when the transistors have the identical macroscopic structure, each transistor may acquire unique characteristic defined by the chemical structure of semiconductor such as variation in impurity concentration. Such unique characteristic will be utilized for identification (as introduced in K. Lofstrom, et al., Tech. Dig. ISSCC, p. 3272 (2000), for example). As a result, by applying transistor to the present invention generating an impurity concentration that randomly varies from one transistor to another, an identification code having little probability of influence of ambient temperature and potential at word line can be obtained.

Regardless of whether binary logic is obtained on the basis of difference in microscopic structure such as crystal structure or difference in chemical structure such as impurity concentration, semiconductor elements to be employed as the first and second semiconductor elements should desirably be identical in macroscopic structure. This is because dependence of electronic characteristic on the shape of the semiconductor element is reduced and further, microscopic and chemical structure may be likely to randomly vary even when the elements are to be manufactured following the same steps. As a result, binary logic and eventually, an identification code is preferably obtained on the basis of such microscopic and chemical structure. The identicalness between the elements in macroscopic structure includes not only the concept of isomorphism but also covers the concept of mirror image. For example, when one semiconductor element includes the rectangular channel region 2 in plan view defined by a channel width W and a channel length L (see FIG. 2) having the same dimensions as those for defining the channel region 2 in another one, these semiconductor elements may be defined to be identical in macroscopic structure at least relative to the channel region 2.

The technique of generating identification code described in the first preferred embodiment may be apparently applicable to the various techniques utilizing identification code as introduced in Japanese Patent Application Laid-Open Nos. 2001-7290 and 2002-073424 corresponding to U.S. patent application Ser. Nos. 09/457,721 and 09/943,026, respectively. And further, such application can be easily realized.

Second Preferred Embodiment

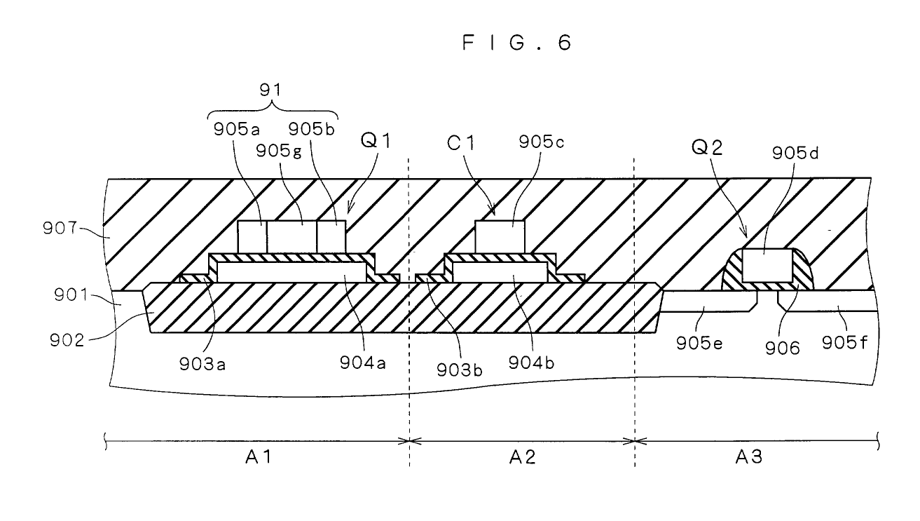

FIG. 6 is a cross-sectional view illustrating the exemplary structure of a semiconductor device according to the second preferred embodiment of the present invention. A semiconductor substrate 901 is divided into regions A1, A2 and A3 including a thin film transistor Q1, a capacitor C1 and an MOS transistor Q2, respectively. In the region A3, impurity regions 905e and 905f are selectively provided in the surface of the semiconductor substrate 901 to be spaced apart from each other. The regions 905e and 905f each serve as either one of source/drain regions of the transistor Q2. A gate electrode 905d is provided at a position opposed to that defined between the impurity regions 905e and 905f in the surface of the semiconductor substrate 901. Together with the sidewalls of the gate electrode 905d, a gate insulating film interposed between the gate electrode 905d and the semiconductor substrate 901 form an insulator 906.

The regions A1 and A2 includes an insulating film 902 for element isolation in the surface of the semiconductor substrate 901. The thin film transistor Q1 and the capacitor C1 are provided on the insulating film 902 for element isolation.

The region A1 includes a gate electrode 904a selectively provided on the insulating film 902 for element isolation. The main surface of the gate electrode 904a, namely, the surface opposite to the semiconductor substrate 901 is planarized. An insulating film 903a covers the main surface, side surfaces of the gate electrode 904a and the outer periphery of the side surfaces thereof, thereby partially covering the insulating film 902 for element isolation. A polycrystalline semiconductor layer 91 is opposed to the gate electrode 904a through the insulating film 903a with an area smaller than that of the main surface of the gate electrode 904a. The polycrystalline semiconductor layer 91 includes a channel region 905g, a source region 905a and a drain region 905b. The insulating film 903a serves as a gate insulating film of the transistor Q1.

The region A2 includes a lower electrode 904b selectively provided on the insulating film 902 for element isolation. An insulating film 903b covers the main surface, side surfaces of the lower electrode 904b and the outer periphery of the side surfaces thereof, thereby partially covering the insulating film 902 for element isolation. An upper electrode 905c is opposed to the lower electrode 904b through the insulating film 903b with an area smaller than that of the main surface of the lower electrode 904b.

The regions A1, A2 and A3 are provided with an interlayer insulating film 907 for covering the transistor Q1, Q2 and the capacitor C1.

FIG. 7 is a plan view illustrating the regions A1 and A2 defined in FIG. 6 omitting illustration of the interlayer insulating film 907. The regions A1 and A2 are illustratively shown in cross section in FIG. 6 taken along a cutting plane line B-B defined in FIG. 7. In FIG. 7, crosses surrounded by squares designate contact holes penetrating the insulating film 903a or 903b and crosses surrounded by circles designate contact holes penetrating the interlayer insulating film 907.

The polycrystalline semiconductor layer 91 is opposed to the gate electrode 904a with an area smaller than that of the main surface of the gate electrode 904a. Therefore, the edges of the source region 905a and the drain region 905b are apart from those of the gate electrode 904a at distances d1 and d2, respectively. In other words, the polycrystalline semiconductor layer 91 dose not reach steps defined by the main surface and the side surfaces of the gate electrode 904a. The regularity in crystal structure resulting from the existence of such step is thereby avoided in the polycrystalline semiconductor layer 91, easily causing variation in crystal structure thereof. For this reason, the thin film transistor Q1 is preferably utilized for obtaining a unique identification code according to the electronic characteristic thereof. Further preferably, the thin film transistor Q1 is further preferably applied to the first preferred embodiment as well as to the various techniques introduced in Japanese Patent Application Laid-Open No. 2001-7290.

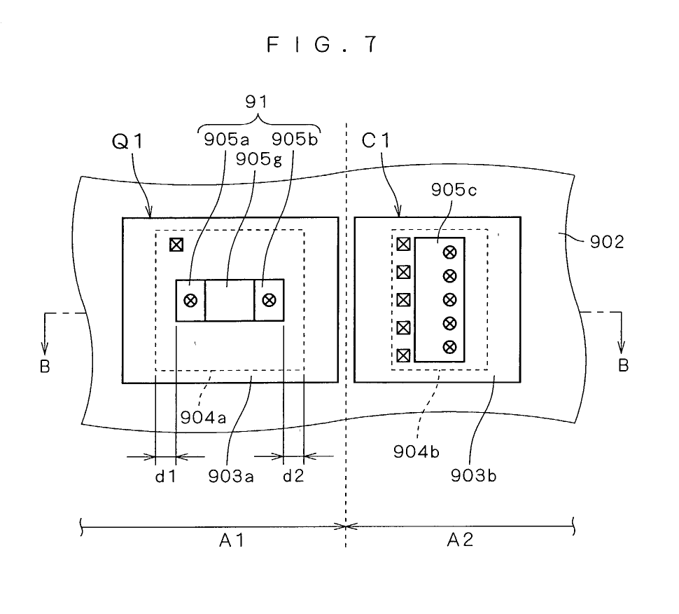

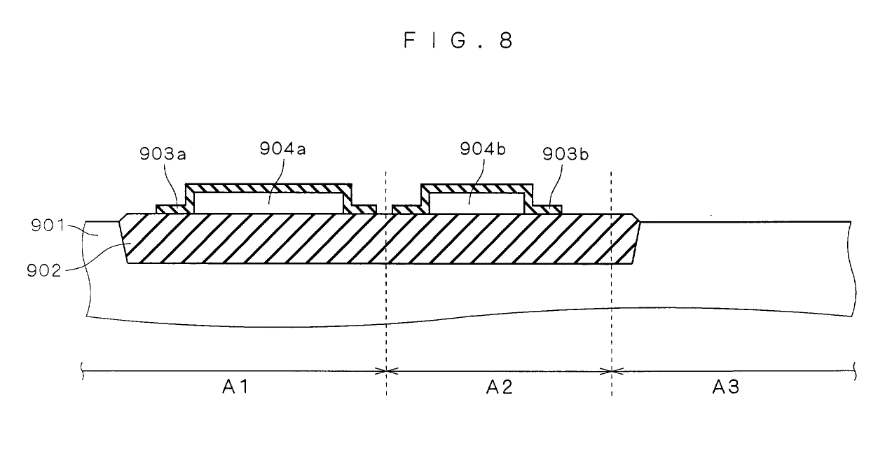

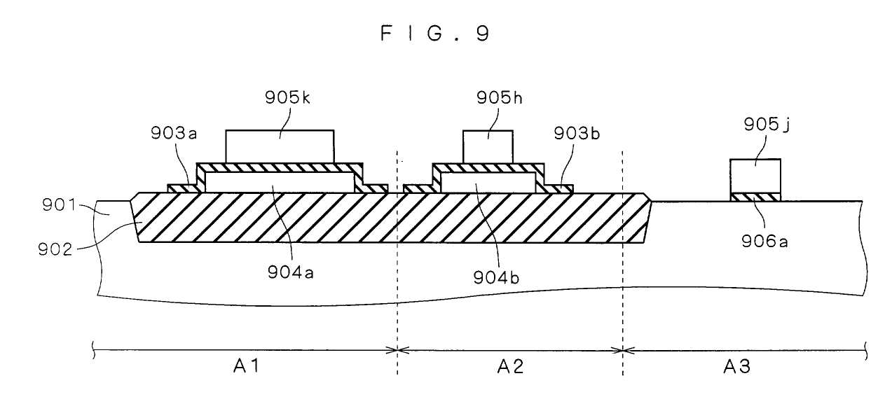

FIGS. 8 and 9 are cross-sectional views each illustrating the exemplary steps of providing the thin film transistor Q1 along with the steps of providing the capacitor C1 and the MOS transistor Q2 following the sequence thereof. With reference to FIG. 8, in the regions A1 and A2, the insulating film 902 for element isolation is provided in the surface of the semiconductor substrate 901. Next, the gate electrode 904a and the lower electrode 904b are respectively provided in the regions A1 and A2. More particularly, polycrystalline silicon is deposited to entirely cover the surfaces of the insulating film 902 for element isolation and the semiconductor substrate 901, for example. After being doped with impurities, this polycrystalline silicon bears conductivity. This polycrystalline silicon is then selectively etched using a lithography technique, thereby forming the gate electrode 904a and the lower electrode 904b.

The insulating films 903a and 903b are thereafter provided. More particularly, a silicon oxide film is deposited to cover the surfaces of the gate electrode 904a, the lower electrode 904b, the insulating film 902 for element isolation and the semiconductor substrate 901, for example. This silicon oxide film is then selectively etched using a lithography technique, thereby forming the insulating films 903a and 903b. Following these steps described so far, the structure illustrated in FIG. 8 is obtained.

With reference to FIG. 9, after providing a gate insulating film 906a in the region A3, polycrystalline semiconductor layers 905k, 905h and 905j are respectively provided on the insulating films 903a, 903b and the gate insulating film 906a. The dimension of the polycrystalline semiconductor layer 905k is smaller than that of the gate electrode 904a in plan view. More particularly, polycrystalline silicon is deposited to cover the surfaces of the insulating films 903a, 903b, the gate insulating film 906a, the insulating film 902 for element isolation and the semiconductor substrate 901, for example. This polycrystalline silicon is then selectively etched using a lithography technique, thereby forming the polycrystalline semiconductor layers 905k, 905h and 905j. Following these steps described so far, the structure illustrated in FIG. 9 is obtained.

Thereafter the polycrystalline semiconductor layers 905k, 905h and 905j are doped with impurities using a patterned resist as a mask, thereby forming the polycrystalline semiconductor layer 91, the upper electrode 905c and the gate electrode 905d, respectively. Also provided are the sidewalls of the MOS transistor Q2 and the interlayer insulating film 907, thereby completing the structure illustrated in FIG. 6.

The foregoing steps for forming the capacitor C1 are publicly known and may be used for facilitating formation of the thin film transistor Q1 according to the second preferred embodiment.

Third Preferred Embodiment

According to the disclosure in Japanese Patent Application Laid-Open No. 2001-7290, by defining an average value d of diameter of crystal grain, the channel length L and the channel width W, range of variation in characteristic of the thin film transistor 101 is shown to be extended. More particularly, in view of the fact that variation in drain current characteristic of the thin film transistor 101 is determined on the basis of variation in amount of crystal grain boundaries 6 defined in the channel region 2, Japanese Patent Application Laid-Open No. 2001-7290 is directed to extend range of variation in amount of the crystal grain boundaries 6 in the channel region 2. When the values of the channel length L and the channel width W are each equal to the average value d of diameter of crystal grain, the drain current characteristic is shown to be most likely to vary. It is further shown that for practical use, each value of the channel length L and the channel width W desirably ranges between 0.5 and 10 times the average value d of diameter of crystal grain, thereby increasing availability.

The third preferred embodiment further suggests desirable relation among these values from a different point of view. FIGS. 10 and 11 are graphs each showing frequency distribution of the length of crystal grain boundary with the channel length L of 1.2 μm and the channel width W of 0.6 μm. Further, the results have been graphed with the average value d of diameter of crystal grain that are 0.48 μm and 3.2 μm in FIGS. 10 and 11, respectively.

In FIG. 10, the distribution of the length of crystal grain boundary is shown in an almost Gaussian curve. In contrast, the distribution of the same is concentrated in rather small values in FIG. 11. Hence, it is obviously known that polycrystalline semiconductor exhibiting distribution shown in FIG. 10 is desirably utilized, thereby obtaining semiconductor element allowing providing binary logic that randomly varies.

With reference to FIG. 2, the difference in distribution of the length of crystal grain between FIGS. 10 and 11 may result from a large difference therebetween in probability of existence of crystal grain boundary in the channel region 2. When the average value d of diameter of crystal grain is smaller than the size of the channel region 2 (as shown in FIG. 10), a crystal grain may be entirely included in the channel region 2 with high probability, thereby providing high probability of existence of crystal grain boundary therein. In contrast, when the average value d of diameter of crystal grain is larger than the size of the channel region 2 (as shown in FIG. 11), the probability of existence of crystal grain boundary in the channel region 2 will be considerably small.

From this point of view, it is seen that the channel length L and the channel width W are each desired to have a value not less than average value d of diameter of crystal grain. In consideration of the foregoing relation provided by Japanese Patent Application Laid-Open No. 2001-7290, further, it is also seen that the channel length L and the channel width W are each desired to have a value that is not less than the same as and not more than 10 times the average value d of diameter of crystal grain.

Fourth Preferred Embodiment

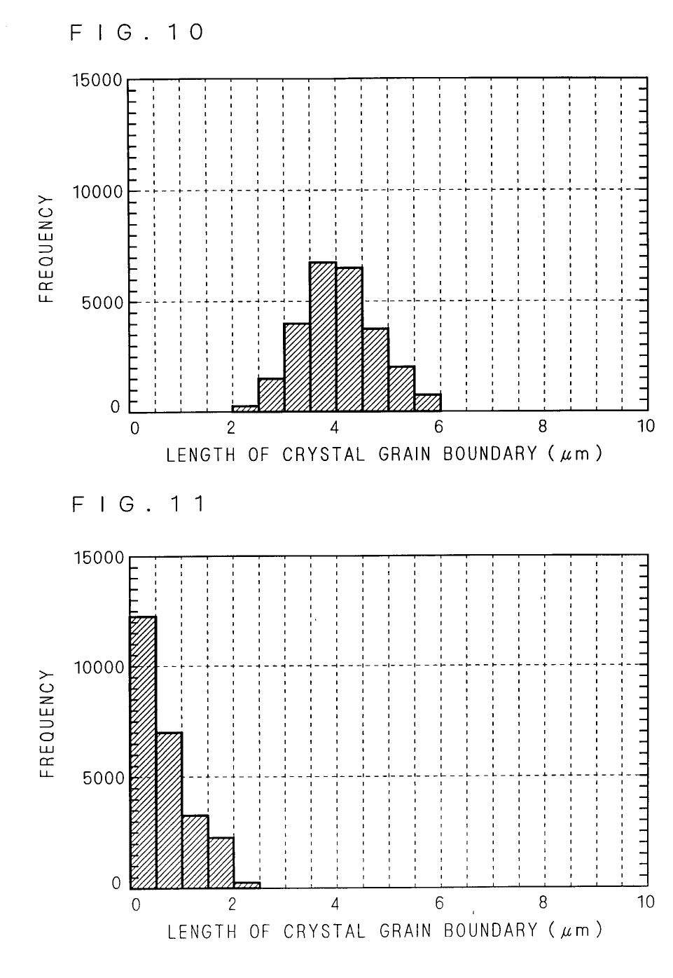

FIG. 12 is a circuit diagram illustrating the structure of a semiconductor integrated circuit according to the fourth preferred embodiment of the present invention. In the fourth preferred embodiment, the positive potential Vcc as described in the first preferred embodiment is applied to the element pairs by a power source line provided to each pair. More particularly, the element pairs 11, 21, 31, 41, . . . each receive the positive potential Vcc by a power source line 81, and the element pairs 12, 22, 32, 42, . . . each receive the positive potential Vcc by a power source line 82. To give further particulars, the source electrodes of the MOS transistors 11a and 11b are connected to each other. Similarly, the source electrodes of the MOS transistors 21a and 21b, the source electrodes of the MOS transistors 31a and 31b, and the source electrodes of the MOS transistors 41a and 41b are respectively connected to each other. Each connection point of the source electrodes in the element pairs 11, 21, 31, 41, . . . is connected to the power source line 81. Similarly, each connection point of the source electrodes in the element pairs 12, 22, 32, 42, . . . is connected to the power source line 82.

As described, by connecting the source electrodes of the two MOS transistors for forming an element pair to the same point of the power source line, these MOS transistors can be compared in electronic characteristic with a higher degree of precision.

FIG. 13 is a plan view illustrating the exemplary structure of the element pair 11 shown in FIG. 12. The element pair 11 includes an approximately Y-shaped polycrystalline silicon layer 10, and the gate electrode 13. The gate electrode 13 includes a contact region 114 for contact with the word line WL1. The polycrystalline silicon layer 10 includes a contact region 115 for contact with the power source line 81, a contact region 116 for contact with the first bit line BL1a, and a contact region 117 for contact with the second bit line BL1b. The polycrystalline silicon layer 10 and the gate electrode 13 defined between the contact regions 115 and 116 form the MOS transistor 11a, and the polycrystalline silicon layer 10 and the gate electrode 13 defined between the contact regions 115 and 117 form the MOS transistor 11b.

The polycrystalline silicon layer 10 defined between the contact regions 115 and 116 includes a source region 3a near the contact region 115, and a drain region 4a near the contact region 116. The polycrystalline silicon layer 10 further includes a channel region 2a between the source region 3a and the drain region 4a. Similarly, the polycrystalline silicon layer 10 defined between the contact regions 115 and 117 includes a source region 3b near the contact region 115, a drain region 4b near the contact region 117, and a channel region 2b between the source region 3b and the drain region 4b. In FIG. 13, the arrangement of the source region 3a, the channel region 2a, and the drain region 4a is shown to be parallel to that of the source region 3b, the channel region 2b, and the drain region 4b. The conductivity type of the source regions 3a and 3b, and the drain regions 4a and 4b is p-type, and the conductivity type of the channel regions 2a and 2b is n-type, for example.

The gate electrode 13 is provided under the channel regions 2a and 2b, extending in a direction substantially orthogonal to the direction in which the source regions 3a, the channel region 2a, and the drain region 4a are arranged. The cross section of such structure in the vicinity of the gate electrode 13 is the same as that of the thin film transistor 101 shown in FIG. 3.

Fifth Preferred Embodiment

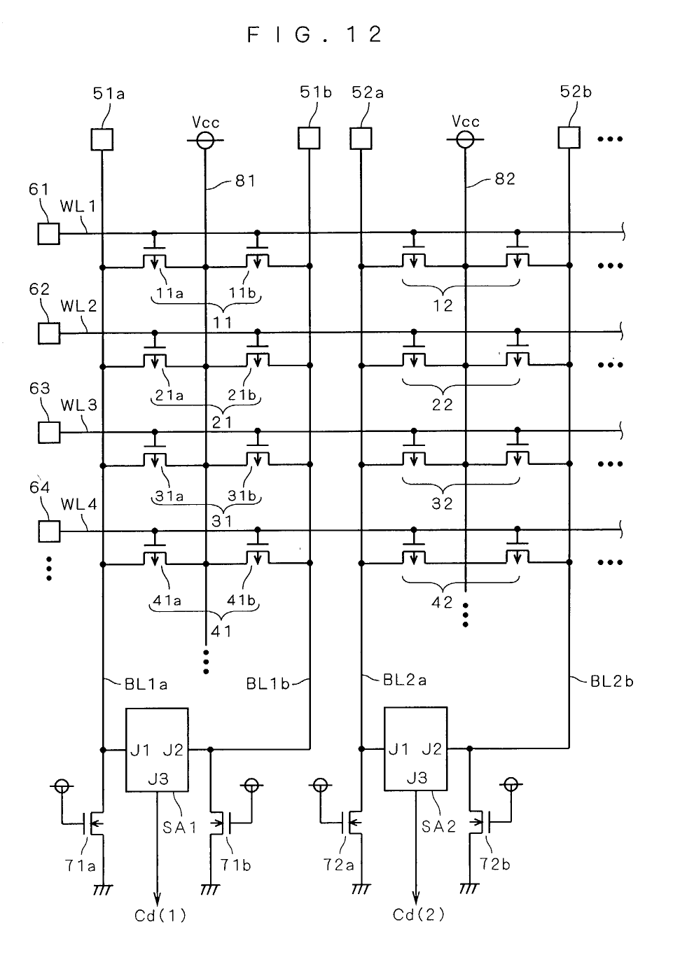

FIG. 14 is a circuit diagram illustrating the structure of a semiconductor integrated circuit according to the fifth preferred embodiment of the present invention. In the fifth preferred embodiment, each element pair for determining binary logic has resistors including polycrystalline semiconductor. More particularly, resistors 11c, 21c, 31c, 41c, . . . and resistors 12c, 22c, 32c, 42c, . . . are provided as first semiconductor elements. Further, resistors 11d, 21d, 31d, 41d, . . . and resistors 12d, 22d, 32d, 42d, are provided as second semiconductor elements. The resistors 11c and 11d form the element pair 11. Similarly, the resistors 21c and 21d, 31c and 31d, 41c and 41d, 12c and 12d, 22c and 22d, 32c and 32d, and 42c and 42d form the element pairs 21, 31, 41, 12, 22, 32 and 42, respectively. These resistors are made of polycrystalline silicon, for example.

In the fifth preferred embodiment, the first and second semiconductor elements are also compared in electronic characteristic, and the result of which is a determinant of binary logic of each element pair. As the first and second semiconductor elements are integrated, they are equally subjected to ambient temperature. The result of comparison therebetween in electronic characteristic is hence unlikely to be subjected to ambient temperature.

In the fifth preferred embodiment, the resistance value of the resistor is used as the foregoing electronic characteristic. The resistance value of the resistor including polycrystalline semiconductor is generally sensitive to the microscopic structure of its polycrystalline semiconductor. As described, in the polycrystalline semiconductor, crystal grains randomly differ thereamong in dimension and location. That is, while the resistors may be identical in macroscopic structure, they are likely to randomly differ thereamong in crystal structure, namely, in microscopic structure thereof. The locations and dimensions of the crystal grain boundaries significantly affecting the resistance value are hence likely to differ between the resistors. In light of this, using the resistors 11c, 21c, 31c, 41c, . . . , 12c, 22c, 32c, 42c, . . . , 11d, 21d, 31d, 41d, . . . and 12d, 22d, 32d, 42d, . . . an identification code can be obtained that randomly differs from one semiconductor integrated circuit to another. Namely, the result of comparison of the resistors in resistance value is preferably utilized for determining binary logic.

In the semiconductor integrated circuit of the fifth preferred embodiment, the resistors 11c, 21c, 31c, 41c, . . . , and 11d, 21d, 31d, 41d, . . . are substituted for the MOS transistors 11a, 21a, 31a, 41a, . . . , and 11b, 21b, 31b, 41b, . . . , respectively, which constitute the semiconductor integrated circuit of the first preferred embodiment shown in FIG. 1. The element pairs 12, 22, 32, 42, . . . include the similar substitutes. More particularly, a gate electrode and a drain electrode of each MOS transistor are respectively substituted by one end and the other end of each resistor. In the fifth preferred embodiment, the potential Vcc to be applied to the source electrode of each MOS transistor is not required and eliminated accordingly.

The other constituent elements including the word lines WL1, WL2, WL3, WL4, pads 61, 62, 63, 64, first bit lines BL1a, BL2a, second bit lines BL1b, BL2b, sense amplifiers SA1, SA2, and the loads 71a, 72a, 71b, 72b are the same as those in the first preferred embodiment.

In the fifth preferred embodiment, the binary logics including Cd(1) and Cd(2) are obtained in the same manner as in the first preferred embodiment. Further, these binary logics can be obtained at a lower price as compared with the first preferred embodiment requiring thin film transistors as the first and second semiconductor elements.

One end of the resistor 11c and one end of the resistor 11d are connected to the word line WL1 at points Z11c and Z11d, respectively. In order to compare the resistors 11c and 11d in resistance value with a high degree of precision, the resistance value of the word line WL1 should desirably be small between the points Z11c and Z11d. As an example, such resistance value is desirably 1/100 the value of the resistors 11c and 11d. Such resistance value of the word line WL1 is required with respect to the other element pairs.

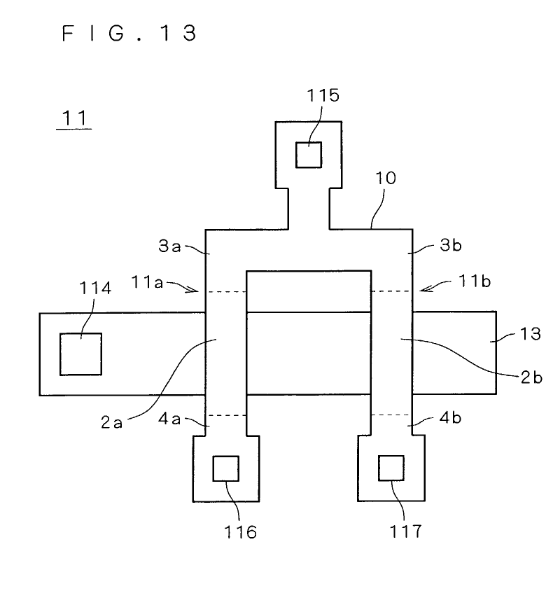

FIG. 15 is a circuit diagram illustrating the structure of a semiconductor integrated circuit according to the preferred modification of the fifth preferred embodiment. In this modification, one end of the resistor 11c and one end of the resistor 11d are connected to the word line WL1 at the same point. The resistors of the other element pairs are connected to the respective word lines in the same way. By employing this connection, the resistance value of the word line WL1 between the points Z11c and Z11d shown in FIG. 14 can be significantly reduced.

FIG. 16 is a plan view illustrating the exemplary structure of the element pair 11 shown in FIG. 15. The element pair 11 is, as a unit, made of polycrystalline silicon 110 having an approximately Y-shaped configuration. The polycrystalline silicon 110 includes a contact region 111 for contact with the word line WL1, a contact region 112 for contact with the first bit line BL1a, and a contact region 113 for contact with the second bit line BL1b. The polycrystalline silicon 110 defined between the contact regions 111 and 112 form the resistor 11c, and the polycrystalline silicon 110 defined between the contact regions 111 and 113 form the resistor 11d.

According to the modification of the fifth preferred embodiment, the resistors 11c and 11d can be compared in resistance value with a higher degree of precision.

Sixth Preferred Embodiment

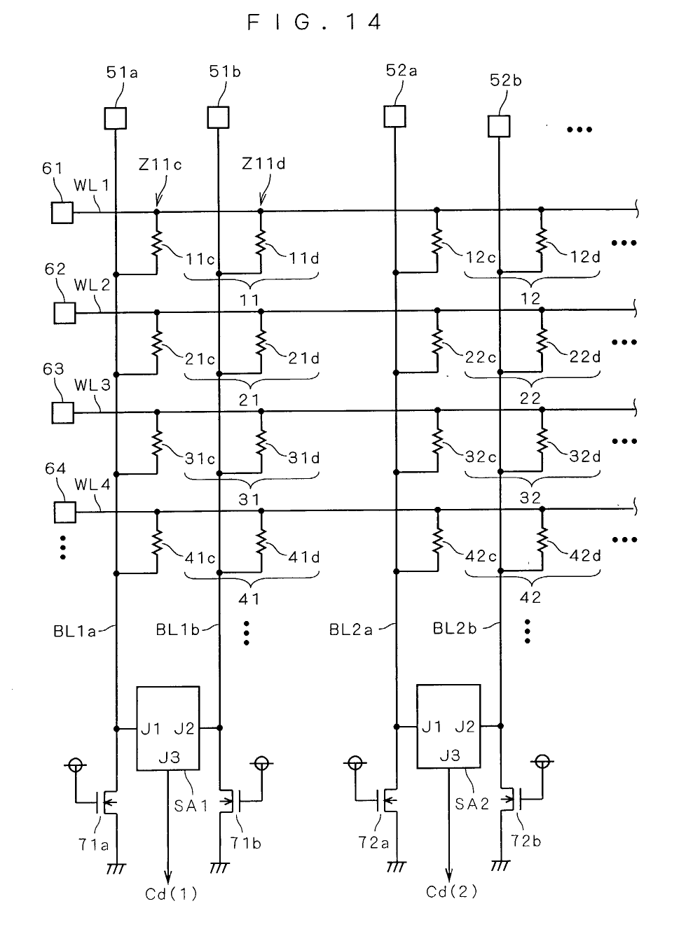

FIG. 17 is a conceptual view schematically illustrating the sixth preferred embodiment of the present invention. As described in Japanese Patent Application Laid-Open Nos. 2001-7290 and 2002-073424, or in the first through fifth preferred embodiments of the present invention, state unique to a semiconductor element can be utilized as a basis for a unique identification code. Therefore, an information terminal equipped with a semiconductor device including such semiconductor element is allowed to transmit its own identification code, thereby informing a destination of its access thereto. It is possible accordingly to keep track of the access condition from the information terminal. Further, as the information terminal utilizes the identification code resulting from the state unique to the semiconductor element therein, it is difficult to commit an unauthorized act of changing one's own identification code and disguising oneself as another person using such information terminal.

For example, a robot and more particularly, a pet-type robot 203 is provided with a semiconductor device 202 having a unique identification code. The identification code in the semiconductor device 202 is transmitted through a communication network 201, thereby notifying a server 200 for constructing the network 201 of the access from the pet-type robot 203. Similarly, a home electrical appliance and more particularly, a refrigerator 205 is provided with a semiconductor device 204 having a unique identification code. A mobile unit and more particularly, an automobile 207 and a card 209 are respectively provided with semiconductor devices 206 and 208 each having a unique identification code. The identification codes included in the semiconductor devices 204, 206 and 208 are transmitted through the communication network 201, thereby notifying the server 200 for constructing the network 201 of the access from the refrigerator 205, from the automobile 207 and from the card 209, respectively.

Seventh Preferred Embodiment

As described above, state unique to a semiconductor element can be utilized as a basis for a unique identification code. As a result, a semiconductor device including such semiconductor element mounted thereon and eventually, a robot including such semiconductor device may be operable according to the identification code unique thereto, thereby developing individuality of the robot.

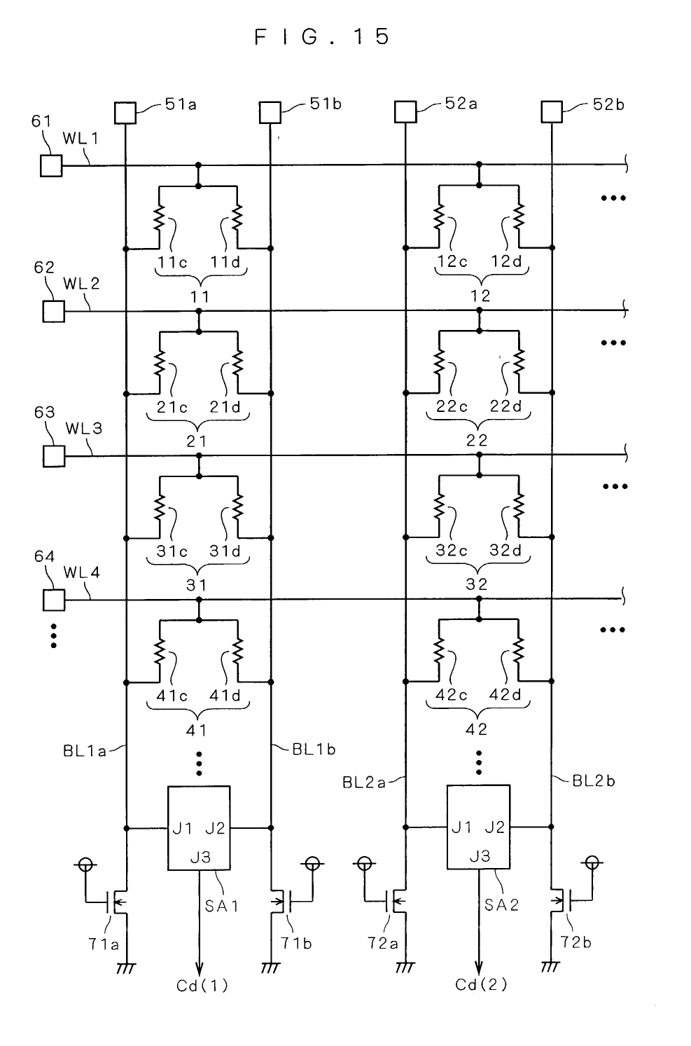

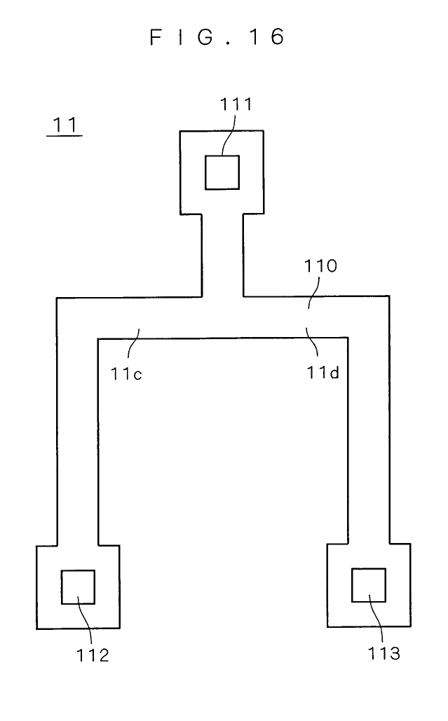

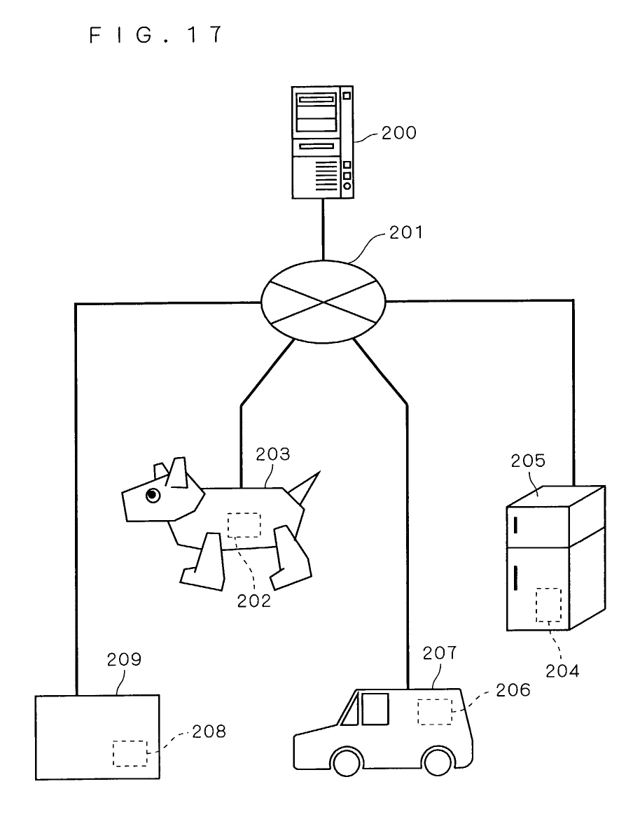

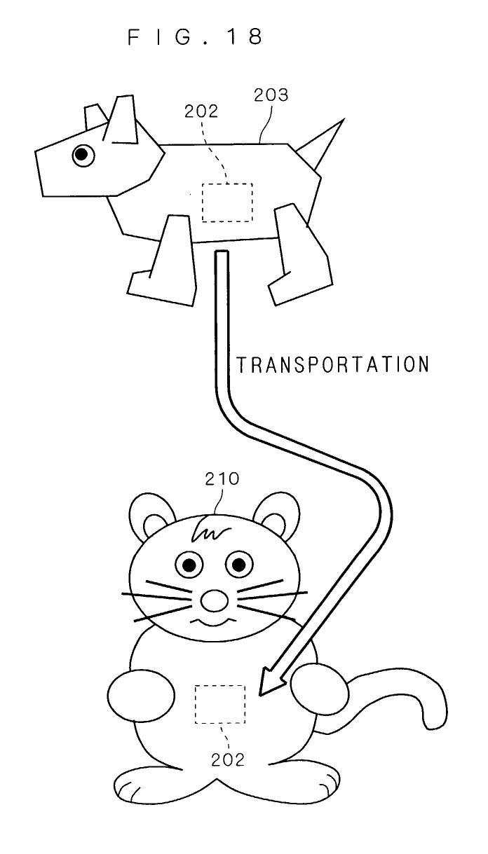

FIG. 18 is a conceptual view schematically illustrating the seventh preferred embodiment of the present invention. According to the specific bit value of the identification code defined by the semiconductor device 202, it is allowed to vary raising speed of the exemplary pet-type robot 203 including the semiconductor device 202 and define handedness of the same. Such individuality is preferable for increasing affection, especially in the pet-type robot.

Further, such individuality of the robot can be a kind of inheritance to another robot. If there occurs breakdown in some part in the pet-type robot 203 other than the semiconductor device 202, the semiconductor device 202 can be transported to a new pet-type robot 210. The pet-type robot 210 is thereby allowed to inherit individuality from the pet-type robot 203.

Eighth Preferred Embodiment

As described above, state unique to a semiconductor element can be utilized as a basis for a unique identification code. As a result, a semiconductor device including such semiconductor element mounted thereon and eventually, a game machine including such semiconductor device may be operable according to random numbers defined on the basis of the unique identification code, thereby enhancing enjoyment in playing a game.

FIG. 19 is a conceptual view schematically illustrating the eighth preferred embodiment of the present invention. A game machine 300 includes a semiconductor device 301 for providing a unique identification code Cd, a timer 302 for giving present time τ, a random number generator 303 for generating random numbers P on the basis of the identification code Cd and the present time τ, a game program storage section 304 for storing a game program and a program execution section 305 for executing a program developed according to the random numbers P and facilitating a game. While these sections are independently illustrated in FIG. 19, they may be integral as a single semiconductor device. Further included in the game machine 300 are an output section 306 and an input section 307.

The random number generator 303 divides τ^{Cd} by (x+1) to determine remainders thereof as the random numbers P. The random numbers relative to 0 through x are thereby determined. Naturally, the random numbers P may be obtained by the alternative calculation as long as the calculation is based on the identification code Cd.

Based on the random numbers P thereby obtained, a game program is executed and a game proceeds. Therefore, a wide range of variation of the game can be enjoyed. A user is allowed to handle the game from the input section 307 while recognizing progress of the game notified from the output section 306.

FIG. 20 is a conceptual view schematically illustrating the sixth preferred embodiment of the present invention in another phase. Game machines 401 and 403 are respectively provided with semiconductor devices 402 and 404 each having a unique identification code. The game machines 401 and 403 are communicatively coupled to each other through a communication network 400. Using the game machines 401 and 403, a competing game can be enjoyed.

In the competing game, identification codes of both players are compared to obtain result of the game.

A competing game guessing identification code of a competitor may be also enjoyed. In this game, one expects the content of one bit of the competitor's identification code and based on the correctness of the expectation, one is allowed to guess the competitor's identification code.

Ninth Preferred Embodiment

Utilizing randomness of a unique identification code provided by a semiconductor element, a management method of lottery will be suggested.

FIG. 21 is a conceptual view schematically illustrating the ninth preferred embodiment of the present invention. A lottery ticket issuer 500 issues a plurality of semiconductor devices 502a, 502b, 502c, 502d, . . . , which may be named as a selling act 503, for example. As described above, the semiconductor devices such as 502a, 502b, 502c and 502d each provide a basis for a unique identification code and therefore, they may be distinguishable thereamong. As a result, by separately setting a winning number, the selected one from the semiconductor devices 502a, 502b, 502c, 502d, . . . can be winning ticket.

The ticket issuer 500 is previously notified of the unique identification codes of the semiconductor devices 502a, 502b, 502c, 502d, . . . , among which a winning number may be selected. Alternatively, a winning number can be defined to be totally independent of the identification codes, resulting in the probability that no winning number can be found in the semiconductor devices 502a, 502b, 502c, 502d, and so forth available for the selling act 503. In this case, the prize accompanied by winning can be carried forward to the next lottery.

FIG. 22 is a conceptual view schematically illustrating the seventh preferred embodiment of the present invention in another phase. A lottery ticket issuer 600 issues a plurality of lottery tickets 602, which may be named as a selling act 603, for example. A winning number setting section 604 includes a semiconductor device 605 having a unique identification code Cd. The winning number setting section 604 makes the identification code Cd public of the semiconductor device 605, which may be called as publication 606. The identification code Cd as made open to the public is utilized as a winning code. It may be probable that no winning code can be found in the plurality of tickets 602 available for the selling act 603. In this case, the prize accompanied by winning can be carried forward to the next lottery.

Alternatively, the identification code of the semiconductor device 605 as illustrated in FIG. 22 is utilized as a winning code and the value of the lottery ticket may be determined on the basis of the degree of difference between the winning code and the identification code of each of the semiconductor devices such as 502a, 502b, 502c and 502d in FIG. 16 available as a ticket. More particularly, the semiconductor device 605 and each of the semiconductor devices 502a, 502b, 502c, 502d, . . . are compared in identification code per bit, for example. When the semiconductor element has the identification code including bits different from those of the winning code and the number of those different bits is not more than a predetermined value, it can be designated as a winning ticket. Further alternatively, a winning code may be naturally defined on the basis of the identification code of the semiconductor device 605.

Tenth Preferred Embodiment

As described, state unique to a semiconductor element can be utilized as a basis for a unique identification code. Therefore, a unique identification code can be assigned to a data medium including such semiconductor element mounted thereon. FIG. 23 illustrates a CD 801 having a unique identification code provided by a semiconductor element. The CD 801 includes a semiconductor device 802 in the vicinity of the inner perimeter thereof.

The semiconductor device 802 includes a semiconductor element 802a bearing unique electronic characteristic. The semiconductor element 802a includes polycrystalline semiconductor, for example, and the crystal structure of which is a determinant of the electronic characteristic of the same. By employing the technique such as the one described in the first preferred embodiment, a unique identification code is obtained on the basis of this electronic characteristic. Therefore, the identification code thus obtained can hardly be copied or rewritten in principle. The data stored in the CD 801 is encrypted using this identification code, for example. As an example, the semiconductor element 802a is mounted on the CD 801 and the data stored in the CD 801 is then encrypted using this identification code. The great difficultly in making a dead copy of the CD 801 is thereby caused.

The identification code unique to the semiconductor device 802 is read by an identification code judging circuit 803. The identification code judging circuit 803 is provided outside the semiconductor device 802, and transmits and receives information to and from the semiconductor device 802 through wireless system. Alternatively, the identification code judging circuit 803 may be arranged in a CD driver (not shown) for reading data from the usual recording region of the CD 801. Power may be also supplied to the semiconductor device 802 from the outside through a wireless system.

Except for the CD, other recording medium such as a DVD may be provided with the semiconductor device as described, to produce the same effect. Alternatively, a banknote, a ticket, or a valuable instrument may be provided with this semiconductor device, to produce the same effect. Further alternatively, this semiconductor device may be provided to medical data such as a medical chart, to prevent tampering.

The semiconductor device as described may be further provided to tangible materials. In this case, the semiconductor device is usable for management of tangible materials such as management of goods and management of collection of waste materials, and the identification code can be read in the same manner as done from the CD.

The semiconductor device including a unique identification code and requiring a low price for manufacture is advantageous, especially when the semiconductor device may be discarded in the situation such as collection of waste materials.

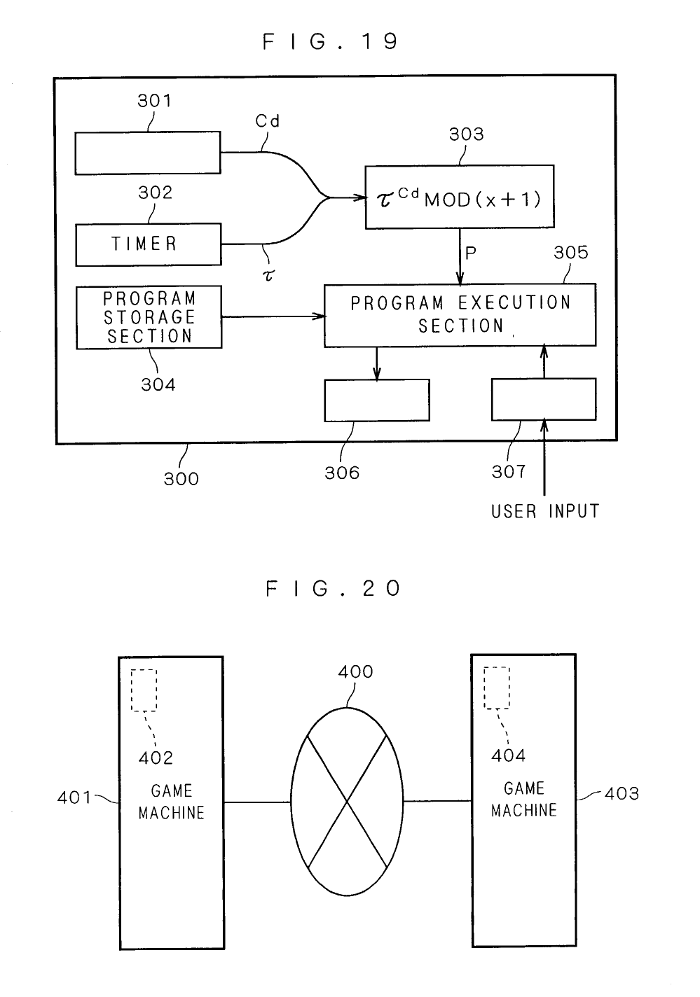

Still alternatively, the semiconductor device including a unique identification code may be mounted on a memory which is electrically readable and writable. FIG. 24 illustrates a memory 804 which is electrically readable and writable, and a semiconductor device 804a providing a unique identification code and mounted on the memory 804. A reader/writer 805 and the memory 804 are electrically connected by an electric wire 806. Therefore, power is also supplied to the memory 804 by the electric wire 806. In addition to the usual data stored in the memory 804, the reader/writer 805 also reads the unique identification code of the semiconductor device 804a.

The semiconductor device 804a has a semiconductor element 804b including polycrystalline semiconductor, for example, and the crystal structure of which is a determinant of the electronic characteristic of the semiconductor element 804b. A unique identification code is obtained on the basis of this electronic characteristic. Therefore, the identification code thus obtained can hardly be copied or rewritten in principle. The data stored in the memory 804 is encrypted using this identification code, for example. As an example, the semiconductor element 804b is mounted on the memory 804 and the data stored in the memory 804 is then encrypted by this identification code. The great difficulty in making a dead copy of the memory 804 is thereby caused.

Eleventh Preferred Embodiment

A unique identification code, to be determined on the basis of unique electronic characteristic of a semiconductor element, may be further assigned to a radio capable of changing its frequency and its system using software, namely, the radio having functions defined in software (hereinafter referred to as “software defined radio”).

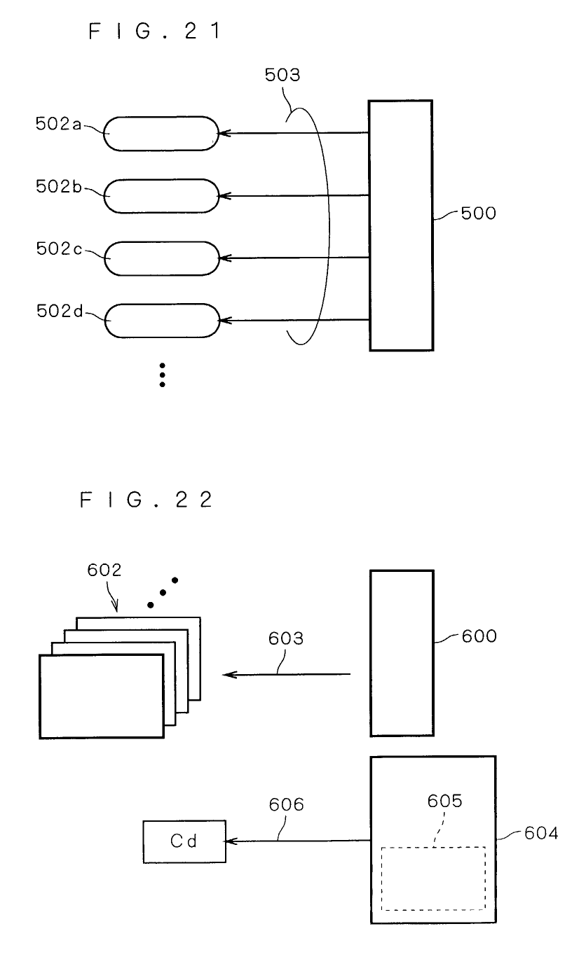

FIG. 25 is a block diagram illustrating the exemplary configuration of a software defined radio 807. The software defined radio 807 includes a memory 808 for storing software that defines the functions of the software defined radio 807, and a decoder 809. The decoder 809 is provided with a semiconductor element 809a therein.

The semiconductor element 809a includes polycrystalline semiconductor, for example, and the crystal structure of which is a determinant of the electronic characteristic of the same. By employing the technique such as the one described in the first preferred embodiment, a unique identification code of the decoder 809 is obtained on the basis of the electronic characteristic of the semiconductor element 809a. Using the unique identification code thus obtained, software is encrypted and then transmitted to the software defined radio 807. As a result, a third person intercepting the software on the way to its destination will find the same unusable.

The transmitting and receiving system of software is not limited to wireless communications. Alternatively, wired communications can be employed to on-line software of a computer, for example. A computer terminal requesting download of software includes a semiconductor element providing a unique identification code, which is used for encrypting software. The software thus encrypted is transmitted to this terminal. In this case, illegal use of the software can be also prevented.

That is, the technique described in the eleventh preferred embodiment can be applied to an apparatus that is generally actuated on receipt of software.

Twelfth Preferred Embodiment

Unique identification data can be embedded in image data and/or sound data as an electronic watermark, for example. As a result, an apparatus handling such image data and/or sound data can be specified.

FIG. 26 is a block diagram illustrating the exemplary configuration of a digital camera 910. The digital camera 910 has a memory 911 for storing picked-up image data 915a, an electronic watermark embedding circuit 912, an identifying semiconductor device 913 provided with a semiconductor element 913a therein bearing unique electronic characteristic, and a recording medium 914.

The semiconductor element 913a includes polycrystalline semiconductor, for example, and the crystal structure of which is a determinant of the electronic characteristic thereof. By employing the technique such as the one described in the first preferred embodiment, a unique identification code of the identifying semiconductor device 913 is obtained on the basis of the electronic characteristic of the semiconductor element 913a. On the basis of the identification code thus obtained, the electronic watermark embedding circuit 912 embeds an electronic watermark in the image data 915a. The resultant image data 915b is stored in the recording medium 914.

The image data 915b thereby stored is provided with an electronic watermark embedded therein corresponding to the digital camera 910 handling the image data 915b. Therefore, an apparatus handling the image data 915b can be specified, leading to prevention of illegal use of image data.

The applicability of the twelfth preferred embodiment is not limited to a digital camera. It can be further applied to a scanner. The twelfth preferred embodiment may be also applied to a recorder for recording digital data, to prevent illegal use of sound data.

Thirteenth Preferred Embodiment

A tag for transmitting a unique identification code to the outside can be embedded in various types of fixed bodies which scarcely move. By recognizing the identification code of the tag, the fixed body provided with this tag embedded therein can be recognized. As a result, a movable body capable of recognizing the identification code of this tag is allowed to detect the position of itself. For example, a tag may be embedded in a road, column, wall, pole, guide path including bumps and dips placed therein, and the like.

As discussed above, when a semiconductor element includes a polycrystalline structure, for example, a unique identification code is generated on the basis of the crystal structure thereof utilizing its unique state. Further, even when this semiconductor element is mass-produced in the same manufacturing flow, the identical elements can be hardly obtained. Without the need of sparing time for storing a unique identification code in each semiconductor element, it is thus allowed to produce identification codes in large quantities that differ thereamong.

A semiconductor device including such semiconductor element may be employed as a tag as discussed, thereby realizing production of the tag at a low price.

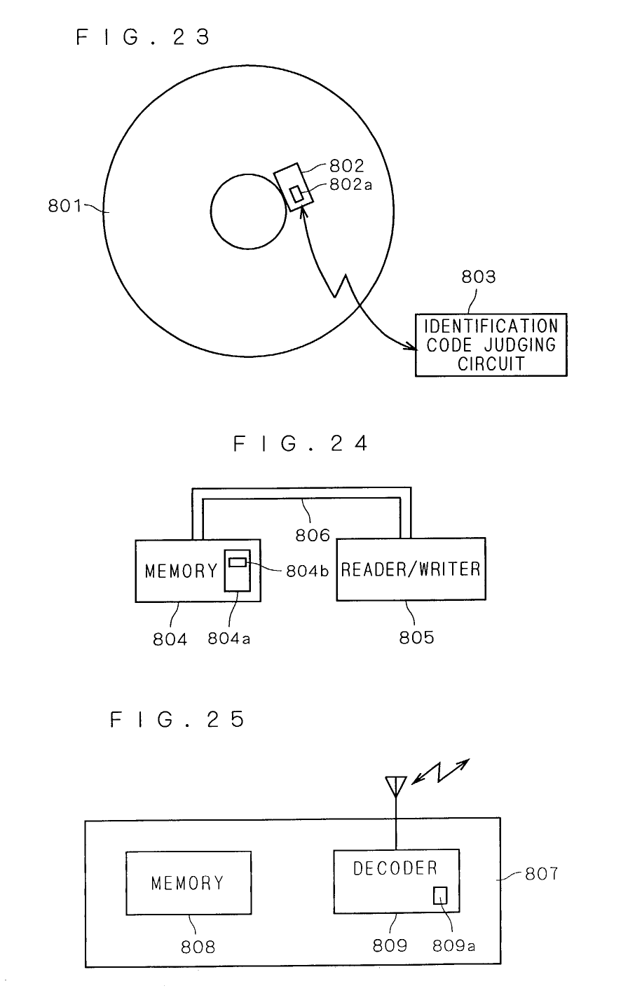

FIG. 27 illustrates how a movable body detects the position of itself. Tags 917a through 917d are embedded in a road 917, a tag 918a is in a pole 918, and tags 919a through 919d are in a guide path 919 including bumps and dips (not shown). The tags 917a through 917d, 918a, and 919a through 919d each use a semiconductor device including the foregoing semiconductor element. By employing the technique such as the one described in the first preferred embodiment, a unique identification code of the semiconductor device is obtained on the basis of the crystal structure of the semiconductor element provided therein.

A movable body 916, which may be a person, for example, has an identification code judging device 916a. Using the system such as wireless communication, the identification code judging device 916a reads identification codes respectively unique to the tags 917a through 917d, 918a, and 919a through 919d.

The identification code judging device 916a judges the identification codes thus read, and informs the position of itself to the movable body 916. For example, the movable body 916 may be informed of the position of the identification code judging device 916a displayed on a map. Alternatively, this position may be informed vocally. Still alternatively, the position may be informed to a third person other than the movable body 916 through wireless system.

The operating power for the tags 917a through 917d, 918a, and 919a through 919d can be supplied from the identification code judging device 916a through wireless system.

In order for the identification code judging device 916a to determine its position as discussed, it is desirable to form and provide a database containing positions of the identification codes unique to the respective tags. On the basis of this database, the position of a subject recognizing the identification codes can be determined in relation to the fixed body.

The exemplary way of forming such database is as follows. First, the identification codes, unique to the respective tags 917a through 917d, 918a, and 919a through 919d that are obtained on the basis of variation in crystal structure (or chemical structure) thereof, are read. Next, a database containing the correlation between the fixed bodies including these tags and the identification codes thus read is formed. The database as formed is supplied and the identification codes contained therein are recognized, to obtain positional information on the fixed bodies.

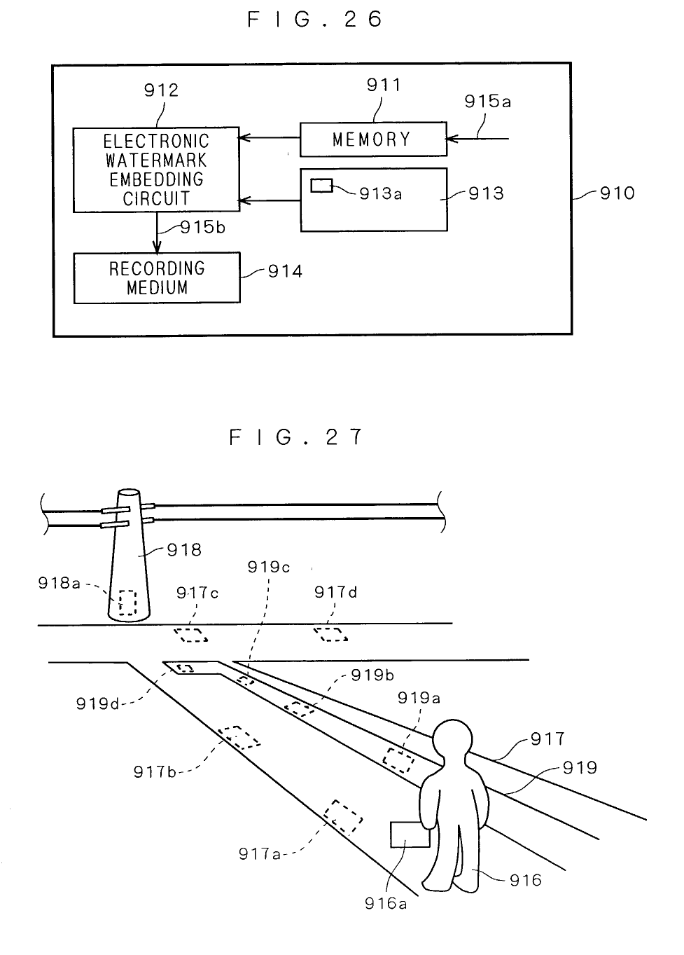

FIG. 28 is a flow chart showing the process flow, starting from embedding of a tag and ending with notification of the position of the identification code judging device 916a by the device 916a to the outside. First, in step S101, a tag is embedded in each fixed body. Thereafter, a database containing the correlation between the position of the fixed body and the identification code unique to the tag embedded therein is formed in step S102. In step S103, the identification code judging device 916a then reads the identification code therearound, to determine the position of itself. Thereafter the identification code judging device 916a notifies its position to the outside in step S104 by outputting the same visually or vocally, for example. The position of the identification code judging device 916a thus outputted is recognized by the movable body, so that movement of the movable body can be assisted.

As described, the identification code unique to the tag provided in the fixed body is recognized, whereby the position of the identification code judging device can be recognized without the need of visually perceiving the fixed body. As a result, when the movable body 916 having the identification code judging device 916a is a person having a disability in the eyes, for example, the movement of the movable body 916 can be assisted by using the technique in the thirteenth preferred embodiment.

Alternatively, when the movable body 916 is a stray child, wandering person, or wandering pet, his, her, or their positions can be recognized by analyzing the communication from the identification code judging device 916a.

FIG. 29 illustrates another exemplary application of the thirteenth preferred embodiment. A vehicle 920 runs on a road 921 provided with a guardrail 922. Tags 921a through 921c are embedded in the road 921, and tags 922a and 922b are embedded in the guardrail 922. The tags 921a through 921c, 922a, and 922b each include the foregoing semiconductor element providing the identification code unique thereto.

The vehicle 920 is provided with an identification code judging device 920a. Using the system such as wireless communication, the identification code judging device 920a reads identification codes respectively unique to the tags 921a through 921c, 922a and 922b. Power may be supplied from the identification code judging device 920a to the tags 921a through 921c, 922a, and 922b.

The identification code judging device 920a analyzes the unique identification codes read out from the tags 921a through 921c, and the result of which is used as a determinant of the position of the vehicle 920. The identification code judging device 920a also analyzes the unique identification codes read out from the tags 922a and 922b, and the result of which is used as a determinant for preventing collision of the vehicle 920 with the guardrail 922.

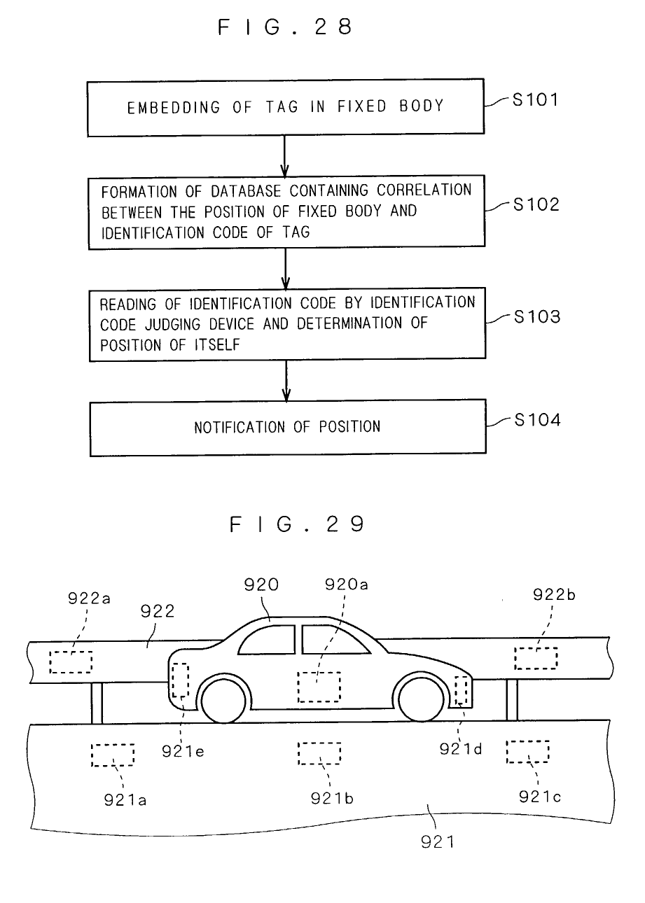

In order for the identification code judging device 920a to easily determine the type of the fixed body using the identification code, it is desirable that each tag further includes constant information corresponding to the type of the fixed body. More particularly, the tags 921a through 921c to be embedded in the road 921 desirably have a common constant code assigned thereto, and the tags 922a and 922b to be embedded in the guardrail 922 desirably have a common constant code assigned thereto. Further preferably, these two constant codes differ therebetween. FIG. 30 is a conceptual view illustrating the exemplary structure of a tag 921m having both a constant code 9211 and a unique identification code 9212.

A semiconductor chip provided with both a constant code and an identification code may be formed by the exemplary method as follows. That is, using a method of making a mask ROM or using an electron beam writing technique that can include any appropriate method known in the art, the portion of the chip corresponding to the constant code is formed, which is then combined with the portion of the chip corresponding to the foregoing identification code that randomly varies from one chip to another. When the semiconductor chip is a mask ROM, for example, a plurality of masks are required for semiconductor chips to form a part of the chip for the constant code. However, as compared with a method of forming all the codes contained in the chip using mask ROMs, cost reduction is realized.

As an example, a code “1010” is used as a constant code of the tags to be embedded in the road 921, and a code “1100” is used as a constant code of the tags to be embedded in the guardrail 922. When the constant code “1100” is detected together with the identification code received by the identification code judging device 920a, and when it is determined that the identification code judging device 920a is in the proximity of the tag providing this identification code, a chance of increasing the distance of the vehicle 920 from the guardrail 922 can be offered.

Similarly, the front end and tail of the vehicle such as bumper may be provided with tags 921d and 921e, to construct the system for preventing collision between vehicles.

The constant code may be alternatively employed as an item code for identifying the type of the item. For example, it may be used as a bar code of a POS system, to keep track of the items. The identification code that randomly varies from one item to another may be employed as the one for identifying each item. As a result, forgery of the item can be prevented.

Fourteenth Preferred Embodiment

A semiconductor element including polycrystalline structure may be employed as a tag for providing a unique identification code which is determined on the basis of the crystal structure therein. A tag can be made at a low cost accordingly. Such tag may be formed in combination with a sensor for measuring environmental conditions such as a temperature sensor, humidity sensor, pressure sensor, and the like. The use for the tag combined with these types of sensors can be found in an extensive field, to keep track of a large amounts of distinct environmental conditions such as whether conditions.

The tag combined with a sensor may detect pressure in a fluid. For example, while moving in an oil pipeline, the tag detects the temperature and pressure of oil, and notifies the detected level to the outside together with its unique identification code.

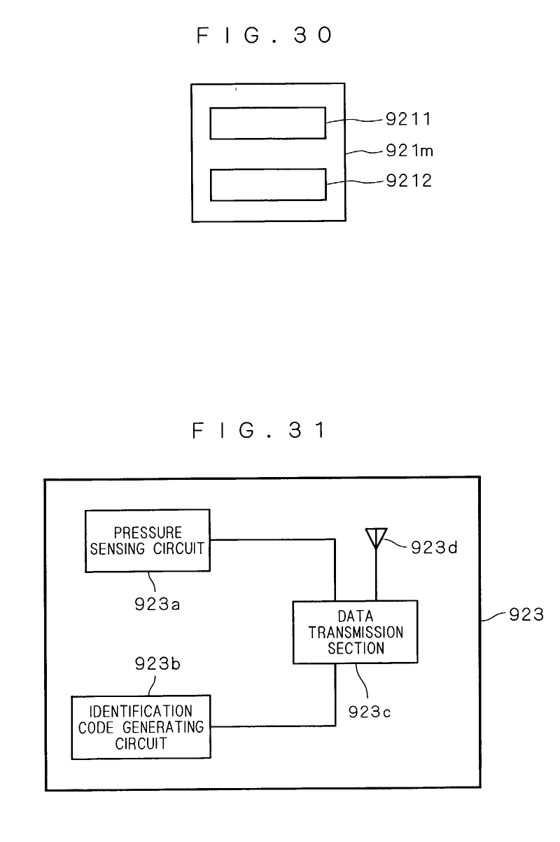

FIG. 31 is a block diagram illustrating the exemplary configuration of an pressure transmission device 923 serving as the tag as described. The pressure transmission device 923 includes a pressure sensing circuit 923a, an identification code generating circuit 923b, a data transmission section 923c, and an antenna 923d.

FIG. 32 is a sectional view partially illustrating the exemplary structure of the pressure sensing circuit 923a. A base body 927 holds thereon an insulating films 925 and 924, and an outer package 926 stacked in this order. The outer package 926 has an opening 929 partially provided therein that is directed toward the outside of the pressure transmission device 923, whereby the insulating film 924 is exposed. At the position facing the opening 929, the base body 927 has an opening selectively provided therein that is directed toward the inside of the pressure sensing circuit 923a. A cavity 930 is defined in this opening. The insulating film 924 defined between the opening 929 and the cavity 930 holds a resistor 928 therein. As an example, the resistor 928 is provided on the insulating film 925 and thereafter, the step of providing the insulating film 924 follows.

On receipt of the pressure applied from the outside of the pressure transmission device 923 through the opening 929 such as the one from oil in the oil pipeline, the resistor 928 is deformed. The cavity 930 facilitates this deformation. The resistance value of the resistor 928 varies according to the deformation thereof. Therefore, the pressure sensing circuit 923a converts the pressure applied from the outside of the pressure transmission device 923 into an electric signal, and supplies the same to the data transmission section 923c.

The identification code generating circuit 923b includes therein a semiconductor element (not shown). By employing the technique such as the one described in the first preferred embodiment, a unique identification code of the semiconductor element is generated. This identification code is supplies to the data transmission section 923c.

On the basis of the identification code received from the identification code generating circuit 923b and the electric signal from the pressure sensing circuit 923a, the data transmission section 923c performs data processing. The result obtained therefrom is transmitted to the outside through the antenna 923d. The correlation between the unique identification code and the pressure of oil can be thus captured from the outside. As a result, safety in oil transport can be significantly assured.

The pressure transmission device 923 may further include therein a driving section for working on its surroundings on the basis of environmental conditions. Such driving section is operative to improve the environmental conditions.

As an example, while moving in a blood vessel, the pressure transmission device 923 detects blood pressure, and notifies the detected level to the outside together with its unique identification code. As a result, diagnosis of an illness can be significantly promoted. Further, a micromachine or a microminiature robot such as an MEMS (micro electro mechanical system) and a semiconductor element having its unique identification code may be combined. Such micromachine removes cholesterol on the inner wall of the blood vessel, for example.

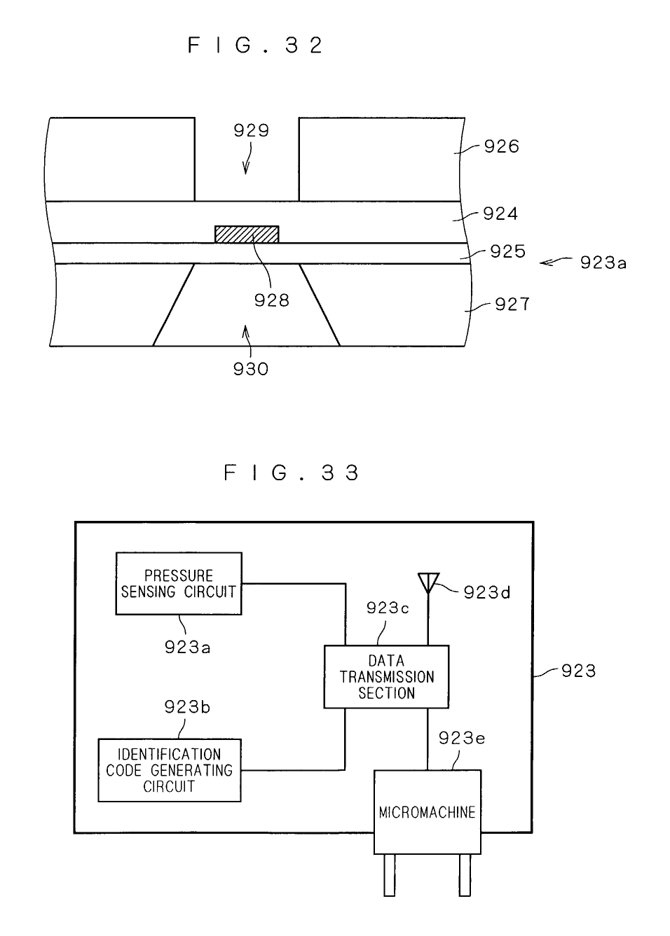

FIG. 33 is a block diagram illustrating the exemplary configuration of the pressure transmission device 923 provided with a micromachine 923e therein as discussed. In a manner similar to that in recognizing oil pressure as discussed, the data transmission section 923c recognizes pressure in the blood vessel. When it is determined that the pressure in the blood vessel is high, the data transmission section 923c actuates the micromachine 923e. When the pressure in the blood vessel is higher than a predetermined level, or when the history of the pressure is stored and this pressure shows upward trend at a predetermined slope with respect to time for a given period, for example, the pressure in the blood vessel is determined to be high.

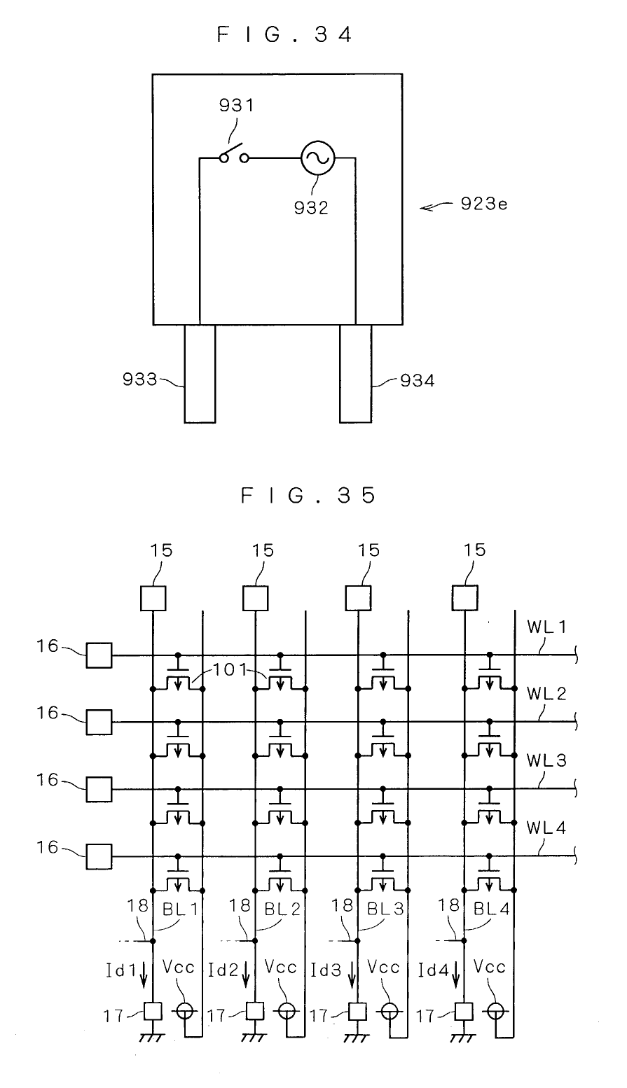

FIG. 34 is a block diagram illustrating the exemplary structure of the micromachine 923e. Electrodes 933 and 934 are exposed to the outside of the pressure transmission device 923. A switch 931 and an AC source 932 are interposed in series between the electrodes 933 and 934. When it is determined that the pressure in the blood vessel is high, the data transmission section 923c turns on the switch 931. An AC voltage is thereby applied between the electrodes 933 and 934.

Accumulation of cholesterol in the blood vessel may be one of the causes of high pressure in the blood vessel. Therefore, when it is determined that the pressure in the blood vessel is high as described, it is desirable to apply AC voltage to the blood vessel, namely, to the blood, whereby cholesterol molecules are moved by dielectric migration. The cholesterol molecules thus moved are thereafter removed by blood flow.

This effect is obtained by the combination of a sensor and a micromachine, which itself is naturally effective. However, when information are to be obtained from a large number of sensors at one time, it is quite important to identify each sensor. In view of this, it is highly advantageous to use a semiconductor element providing its unique identification code as a tag to be combined with a sensor.

The semiconductor element to be employed in the sixth through thirteenth preferred embodiments is not limited to polycrystalline semiconductor. As long as the identification code is defined on the basis of variation in chemical structure such as impurity concentration, any type of semiconductor elements can be employed.

### INCORPORATION BY REFERENCE

The entire contents of a copending U. S. patent application Ser. No. 09/457,721, filed on Dec. 10, 1999, entitled “Semiconductor Device, Method of Manufacturing Semiconductor Device and Communication Method”, and a copending U.S. patent application Ser. No. 09/943,026, filed on Aug. 31, 2001, entitled “Semiconductor Device, Terminal Device and Communication Method”, both of which assigned to the assignee of the present application, are incorporated herein by reference.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a plurality of element pairs each including a first semiconductor element and a second semiconductor element, wherein
said first semiconductor element and said second semiconductor element are compared in electronic characteristic, a result of which being utilized for determining a binary logic for each of said plurality of element pairs.

2. The semiconductor device according to claim 1, wherein
said first semiconductor element and said second semiconductor element are each an MOS transistor comprising a source electrode, a drain electrode and a gate electrode,
said source electrode of said first semiconductor element and said source electrode of said second semiconductor element receive the same fixed potential of a predetermined value applied thereto, and
said first semiconductor element and said second semiconductor element are compared in characteristic of a drain current relative to a gate potential, a result of which being utilized for determining said binary logic for each of said plurality of element pairs.

3. The semiconductor device according to claim 2, further comprising:
at least one word line connected to said gate electrode of said first semiconductor element and said gate electrode of said second semiconductor element in each of said plurality of element pairs.

4. The semiconductor device according to claim 3, wherein
said at least one word line includes a plurality of word lines,
said semiconductor device further comprising:
a first bit line connected to each one of said drain electrodes of said first semiconductor elements that are connected to separate ones of said plurality of word lines;
a second bit line connected to each one of said drain electrodes of said second semiconductor elements that are connected to separate ones of said plurality of word lines; and
at least one sense amplifier for comparing said first bit line and said second bit line in magnitude of current flowing therethrough.

5. The semiconductor device according to claim 1, wherein
said first semiconductor element and said second semiconductor element are identical in macroscopic structure.

6. The semiconductor device according to claim 5, wherein
said first semiconductor element and said second semiconductor element both include polycrystalline semiconductor.

7. The semiconductor device according to claim 2, wherein
said source electrode of said first semiconductor element and said source electrode of said second semiconductor element receive said fixed potential of said predetermined value applied thereto at the same position.

8. The semiconductor device according to claim 7, wherein
said first semiconductor element and said second semiconductor element define a polycrystalline semiconductor layer having an approximately Y-shaped configuration.

9. The semiconductor device according to claim 1, wherein
said first semiconductor element and said second semiconductor element are each an MOS transistor, comprising:
a gate electrode having a planarized main surface;
a gate insulating film; and
a polycrystalline semiconductor layer including a channel region, a source region and a drain region, said polycrystalline semiconductor layer being opposed to said gate electrode through said gate insulating film with an area smaller than that of said main surface.

10. The semiconductor device according to claim 1, wherein
said first semiconductor element and said second semiconductor element are each an MOS transistor comprising a channel region including polycrystalline semiconductor, and
at least one of a channel width and a channel length of said channel region has a value that is not less than the same as and not more than 10 times an average value of a diameter of a crystal grain in said polycrystalline semiconductor.

11. The semiconductor device according to claim 1, wherein
said first semiconductor element and said second semiconductor element are each a resistor having a first end and a second end,
said semiconductor device further comprising:
at least one word line connected to said first end of said first semiconductor element and said first end of said second semiconductor element in each of said plurality of element pairs.

12. The semiconductor device according to claim 11, wherein
said at least one word line includes a plurality of word lines,
said semiconductor device further comprising:
a first bit line connected to each one of said second ends of said first semiconductor elements that are connected to separate ones of said plurality of word lines;
a second bit line connected to each one of said second ends of said second semiconductor elements that are connected to separate ones of said plurality of word lines; and
at least one sense amplifier for comparing said first bit line and said second bit line in magnitude of current flowing therethrough.

13. The semiconductor device according to claim 11, wherein
said first semiconductor element and said second semiconductor element are identical in macroscopic structure.

14. The semiconductor device according to claim 13, wherein
said first semiconductor element and said second semiconductor element both include polycrystalline semiconductor.

15. The semiconductor device according to claim 11, wherein
said first semiconductor element and said second semiconductor element define a polycrystalline semiconductor layer having an approximately Y-shaped configuration.

16. A semiconductor device, comprising:
a gate electrode having a planarized main surface;
a gate insulating film; and
a polycrystalline semiconductor layer including a channel region, a source region and a drain region, said polycrystalline semiconductor layer being opposed to said gate electrode through said gate insulating film with an area smaller than that of said main surface.

17. A semiconductor device, comprising:
a channel region including polycrystalline semiconductor, wherein
at least one of a channel width and a channel length of said channel region has a value that is not less than the same as and not more than 10 times an average value of a diameter of a crystal grain in said polycrystalline semiconductor.

18. A semiconductor device, comprising:
a polycrystalline semiconductor layer of an approximately Y-shaped configuration, said polycrystalline semiconductor layer having a first end, a second end and a third end, and
a gate electrode crossing said polycrystalline semiconductor layer defined between said first end and said third end, said gate electrode further crossing said polycrystalline semiconductor layer defined between said second end and said third end, wherein
said first end serves as a drain of a first transistor,
said second end serves as a drain of a second transistor, and
said third end serves as a source of said first and second transistors.
